(19) United States
(12) Patent Application Publication
(10) Pub. No.: US 2026/0247903 A1
(43) Pub. Date: Aug. 20, 2026

(54) DESIGNS OF NANO-PRECISE SHORT STROKE STAGES FOR ACTUATION

(71) Applicant: Board of Regents, The University of Texas System, Austin, TX (US)

(72) Inventors: Sidlgata V. Sreenivasan, Austin, TX (US); Jay Shah, Austin, TX (US); Paras Ajay, Austin, TX (US)

(21) Appl. No.: 19/161,284

(22) PCT Filed: Mar. 1, 2024
(86) PCT No.: PCT/US2024/018093

§ 371 Date: Sep. 1, 2025

Related U.S. Application Data
(60) Provisional application No. 63/449,357, filed on Mar. 2, 2023.

(51) Int. Cl. H10P 72/00

(52) U.S. Cl. CPC H10P 72/0438

(57) ABSTRACT

A system for aligning four or more dies with respect to a substrate. The system includes four or more stage modules utilized to enable the aligning of the four or more dies with respect to the substrate. The aligning is performed with sub-50 nm alignment precision, where the four or more stage modules are actuated along the X, Y, and/or θ_{Z} directions. The motion along the Z, θ_{X}, and/or θ_{Y} directions is supported actively or passively, where the passive supporting is enabled by flexures and/or a liquid film. Furthermore, actuation is enabled by piezoelectric and/or electromagnetic methods.

### CROSS REFERENCE TO RELATED APPLICATIONS

This application claims priority to U.S. Provisional Patent Application Ser. No. 63/449,357 entitled “Nano-Precise Short-Stroke Stages,” filed on Mar. 2, 2023, which is incorporated by reference herein in its entirety.

### TECHNICAL FIELD

The present disclosure relates generally to a short-stroke wafer stage system, and more particularly to nano-precise short stroke stages for actuation.

### BACKGROUND

Currently, for the short stroke stage that carries the substrate, sub-nm motion performance is obtained through 6 degrees of freedom (DoF) actuation and metrology. Due to optimization of actuator efficiency and rigid body motion control, historically moving mass in stages could be kept fairly constant over time. Analyses on throughput improvement options, however, show that this trend will no longer hold, primarily due to electromagnetic and power amplifier limitations. To meet future productivity and overlay requirements, moving mass has to be reduced significantly. This will be required to stretch existing 300 mm technology, but in particular to enable future 450 mm generations. Although a potential transfer is still unsure and wafer generation targets remain unchanged by the International Roadmap Committee, is it considered important to assess standards and productivity improvement options for both generations. For the 450 mm generation, stages and overlay systems development are among the key-issues for the 32 nm node and beyond.

Unfortunately, there is not currently a means for the required precision of the short stroke stages to address such issues. In particular, there is not currently a means for nano-precise short stroke stages for actuation.

### SUMMARY

In one embodiment of the present disclosure, a system for aligning and bonding four or more dies with respect to a substrate comprises four or more stage modules utilized to enable the aligning of the four or more dies with respect to the substrate. The aligning is performed with sub-50 nm alignment precision, where the four or more stage modules are actuated along one or more of X, Y, and θ_{Z} directions.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE DRAWINGS

A better understanding of the present invention can be obtained when the following detailed description is considered in conjunction with the following drawings, in which:

FIG. 1 illustrates an array of short stroke stages for fine alignment and bonding of two or more, four or more, five or more, six or more, eight or more, ten or more, twelve or more, fifteen or more, twenty or more, thirty or more, fifty or more, or hundred or more dies with respect to one substrate or corresponding number of substrates in accordance with an embodiment of the present disclosure;

FIG. 2 illustrates the top view of the positioning stage schematics in accordance with an embodiment of the present disclosure;

FIG. 3 illustrates the front sectional view of the positioning stage schematics in accordance with an embodiment of the present disclosure;

FIG. 4A illustrates an in-plane flexure mechanism in accordance with an embodiment of the present disclosure;

FIG. 4B illustrates the direction of motion allowed by a single crab-leg in accordance with an embodiment of the present disclosure;

FIG. 5A illustrates an in-plane flexure mechanism in accordance with an embodiment of the present disclosure;

FIG. 5B illustrates the direction of motion of a single cross flexure element, including across the intermediate body, in accordance with an embodiment of the present disclosure;

FIG. 6A illustrates double parallelogram structures arranged serially to provide motion in directions X and Y with a significant motion range in both directions in accordance with an embodiment of the present disclosure;

FIG. 6B illustrates the structure of a double parallelogram element in accordance with an embodiment of the present disclosure;

FIG. 7A illustrates flexure units connected to a mover in accordance with an embodiment of the present disclosure;

FIG. 7B illustrates the structure of a flexure unit of FIG. 7A in accordance with an embodiment of the present disclosure;

FIG. 8A illustrates flexure units arranged serially in orthogonal directions to allow the motion of the mover in two directions in accordance with an embodiment of the present disclosure;

FIG. 8B illustrates the structure of a flexure unit of FIG. 8A in accordance with an embodiment of the present disclosure;

FIG. 9A illustrates an actuator attached along an axis which is out of plane of the mover in accordance with an embodiment of the present disclosure;

FIG. 9B illustrates an actuator attached along an axis which is orthogonal to the axis of the desired motion of the mover in accordance with an embodiment of the present disclosure;

FIG. 10A illustrates a double slider out-of-plane mechanism in accordance with an embodiment of the present disclosure;

FIG. 10B illustrates a top view of the double slider out-of-plane mechanism in accordance with an embodiment of the present disclosure;

FIG. 10C illustrates a side view of the double slider out-of-plane mechanism in accordance with an embodiment of the present disclosure;

FIG. 10D illustrates another side view of the double slider out-of-plane mechanism in accordance with an embodiment of the present disclosure;

FIG. 10E illustrates an additional side view of the double slider out-of-plane mechanism of FIG. 10D in accordance with an embodiment of the present disclosure;

FIG. 10F illustrates a top view of the side view of the double slider out-of-plane mechanism of FIG. 10D in accordance with an embodiment of the present disclosure;

FIG. 11A illustrates the out-of-plane flexure mechanism in accordance with an embodiment of the present disclosure;

FIG. 11B illustrates a front view of the out-of-plane flexure mechanism in accordance with an embodiment of the present disclosure;

FIG. 11C illustrates a top view of the front view of the out-of-plane flexure mechanism of FIG. 11B in accordance with an embodiment of the present disclosure;

FIG. 11D illustrates a side view of the front view of the out-of-plane flexure mechanism of FIG. 11B in accordance with an embodiment of the present disclosure;

FIG. 11E illustrates a side view of the out-of-plane flexure mechanism in accordance with an embodiment of the present disclosure;

FIG. 11F illustrates a top view of the out-of-plane flexure mechanism in accordance with an embodiment of the present disclosure;

FIG. 11G illustrates the structure of a flexure unit as a single flexure in accordance with an embodiment of the present disclosure;

FIG. 11H illustrates the structure of flexure unit as a parallelogram structure in accordance with an embodiment of the present disclosure;

FIG. 11I illustrates the structure of flexure unit as a double parallelogram structure in accordance with an embodiment of the present disclosure;

FIG. 12A illustrates an exemplary out-of-plane flexure mechanism where flexures diverge from the input block to two separate output blocks in accordance with an embodiment of the present disclosure;

FIG. 12B illustrates an alternative embodiment of the out-of-plane flexure mechanism where flexures diverge from the input block to a single output block in accordance with an embodiment of the present disclosure;

FIG. 13A illustrates an out-of-plane flexure straight line mechanism in accordance with an embodiment of the present disclosure;

FIG. 13B illustrates a flexure unit that is used in FIG. 13A as a single flexure in accordance with an embodiment of the present disclosure;

FIG. 13C illustrates a flexure unit that is used in FIG. 13A as a parallelogram structure in accordance with an embodiment of the present disclosure;

FIG. 13D illustrates a flexure unit that is used in FIG. 13A as a double parallelogram structure in accordance with an embodiment of the present disclosure;

FIG. 14 illustrates a lever type out-of-plane mechanism in accordance with an embodiment of the present disclosure;

FIG. 15A illustrates a top view of the support flexure unit with a stator in accordance with an embodiment of the present disclosure;

FIG. 15B illustrates a cross-sectional front view of the support flexure unit with a stator in accordance with an embodiment of the present disclosure;

FIG. 15C illustrates a cross-sectional side view of the support flexure unit with a stator in accordance with an embodiment of the present disclosure;

FIG. 16A illustrates a schematic of a mechanism utilizing a passive flexure mechanism in conjunction with an actuator that actuates in a vertical motion in accordance with an embodiment of the present disclosure;

FIG. 16B illustrates a schematic of a mechanism utilizing a passive flexure mechanism in conjunction with an actuator that actuates in a horizontal motion in accordance with an embodiment of the present disclosure;

FIG. 17A illustrates the side view of a passive flexure mechanism in accordance with an embodiment of the present disclosure;

FIG. 17B illustrates the front view of the passive flexure mechanism of FIG. 17A in accordance with an embodiment of the present disclosure;

FIG. 18A illustrates the front view of a passive flexure mechanism in accordance with an embodiment of the present disclosure;

FIG. 18B illustrates the top view of the passive flexure mechanism of FIG. 18A in accordance with an embodiment of the present disclosure;

FIG. 18C illustrates an expanded form of the flexure unit of the passive flexure mechanism of FIG. 18A in accordance with an embodiment of the present disclosure;

FIG. 19A illustrates a side view of the passive flexure mechanism utilizing a hinge flexure in accordance with an embodiment of the present disclosure;

FIG. 19B illustrates a front view of the passive flexure mechanism utilizing a hinge flexure in accordance with an embodiment of the present disclosure;

FIG. 20A illustrates thermal action performed through a power light emitting diode (LED) in accordance with an embodiment of the present disclosure;

FIG. 20B illustrates thermal action performed through an actively controlled heat exchanger in accordance with an embodiment of the present disclosure;

FIG. 21A illustrates an architecture for packaging actuators in accordance with an embodiment of the present disclosure;

FIG. 21B illustrates an alternative architecture for packaging actuators in accordance with an embodiment of the present disclosure;

FIG. 21C illustrates a further alternative architecture for packaging actuators in accordance with an embodiment of the present disclosure;

FIG. 22A illustrates an actuator-stage interface placement architecture in accordance with an embodiment of the present disclosure;

FIG. 22B illustrates an alternative actuator-stage interface placement architecture in accordance with an embodiment of the present disclosure;

FIG. 22C illustrates a further alternative actuator-stage interface placement architecture in accordance with an embodiment of the present disclosure;

FIG. 23A illustrates a mechanism for θ_{Z} actuation in accordance with an embodiment of the present disclosure;

FIG. 23B illustrates linear springs in accordance with an embodiment of the present disclosure;

FIG. 23C illustrates a torsional spring in accordance with an embodiment of the present disclosure;

FIG. 24A illustrates actuator stability without in-plane support flexure units for actuator stabilization in accordance with an embodiment of the present disclosure;

FIG. 24B illustrates actuator stability with in-plane support flexure units for actuator stabilization in accordance with an embodiment of the present disclosure;

FIG. 25A illustrates a mover connected with output blocks of the out-of-plane flexure mechanisms in accordance with an embodiment of the present disclosure;

FIG. 25B illustrates the layout of the mover with flexures for actuator stability in accordance with an embodiment of the present disclosure;

FIG. 25C illustrates the corresponding schematic of the actuator-stage interface in accordance with an embodiment of the present disclosure;

FIG. 25D illustrates the support flexure unit as a single flexure in accordance with an embodiment of the present disclosure;

FIG. 25E illustrates the support flexure unit as a parallelogram structure in accordance with an embodiment of the present disclosure;

FIG. 25F illustrates the support flexure unit as a double parallelogram structure in accordance with an embodiment of the present disclosure;

FIG. 25G illustrates a sectional view of the support flexure units in accordance with an embodiment of the present disclosure;

FIG. 26 illustrates a flexure and liquid bearing interface in accordance with an embodiment of the present disclosure;

FIG. 27 illustrates a commutative planar motor-based nano-precise positioning stage in accordance with an embodiment of the present disclosure;

FIG. 28A illustrates a top view of magnetic field lines coming out of plane from the magnet array in accordance with an embodiment of the present disclosure;

FIG. 28B illustrates a top view of magnetic field lines going into the plane from the magnet array in accordance with an embodiment of the present disclosure;

FIG. 29A illustrates a top view of an array of magnets in a first arrangement in a manner that north and south poles alternatively face the coil array in accordance with an embodiment of the present disclosure;

FIG. 29B illustrates a top view of an array of magnets in a second arrangement in a manner that north and south poles alternatively face the coil array in accordance with an embodiment of the present disclosure;

FIG. 30 is a top view of magnets arranged in such a way that north and south poles alternatively face the coil array in accordance with an embodiment of the present disclosure;

FIG. 31A illustrates a top view of an array of magnets in a first arrangement in a one-dimensional Halbach array in accordance with an embodiment of the present disclosure;

FIG. 31B illustrates a top view of an array of magnets in a second arrangement in a one-dimensional Halbach array in accordance with an embodiment of the present disclosure;

FIG. 32 illustrates a top view of an array of magnets in a two-dimensional Halbach array in accordance with an embodiment of the present disclosure;

FIG. 33A illustrates a coil array, where each coil of the coil array is a planar spiral, in accordance with an embodiment of the present disclosure;

Referring to FIG. 33B, FIG. 33B illustrates the magnetic field produced by current carrying coils in accordance with an embodiment of the present disclosure;

FIG. 34A illustrates a coil array, where each coil of the coil array is a helix, in accordance with an embodiment of the present disclosure;

FIG. 34B illustrates a cross-section of the coil array of FIG. 34A in accordance with an embodiment of the present disclosure;

FIG. 34C illustrates the cross-sectional front view of the coil in accordance with an embodiment of the present disclosure;

FIG. 34D illustrates the cross-sectional inverted back view of the coil in accordance with an embodiment of the present disclosure;

FIG. 34E illustrates the layer-by-layer fabrication of the helical coil in accordance with an embodiment of the present disclosure;

FIG. 35A illustrates a coil array, where each coil of the coil array is a closed polygon, with sharp corners or rounded corners, in accordance with an embodiment of the present disclosure;

FIG. 35B illustrates a front view of FIG. 35A in accordance with an embodiment of the present disclosure;

FIG. 36A illustrates individual coil elements being grouped together and having those groups being arranged orthogonal to each other in accordance with an embodiment of the present disclosure;

FIG. 36B illustrates individual coil elements in different orientations stacked in different planes in accordance with an embodiment of the present disclosure;

FIG. 37 is a flowchart of a method for fabricating an array of magnets in accordance with an embodiment of the present disclosure;

FIGS. 38A-38D depict the cross-sectional views for fabricating an array of magnets using the steps described in FIG. 37 in accordance with an embodiment of the present disclosure;

FIG. 39A illustrates a top view of non-commutative planar-motor (electromagnetic) based actuation in accordance with an embodiment of the present disclosure;

FIG. 39B illustrates a front view of non-commutative planar-motor (electromagnetic) based actuation in accordance with an embodiment of the present disclosure;

FIG. 40 illustrates an exemplary coil and magnet arrangement in accordance with an embodiment of the present disclosure;

FIG. 41A illustrates a top view of copper traces forming a square helical coil structure in accordance with an embodiment of the present disclosure;

FIG. 41B illustrates a front view of copper traces forming a square helical coil structure in accordance with an embodiment of the present disclosure;

FIG. 41C illustrates a bottom view of copper traces forming a square helical coil structure in accordance with an embodiment of the present disclosure; and

FIG. 41D illustrates the resultant square helical coil structure in accordance with an embodiment of the present disclosure.

### DETAILED DESCRIPTION

As stated above, currently, for the short stroke stage that carries the substrate, sub-nm motion performance is obtained through 6 degrees of freedom (DoF) actuation and metrology. Due to optimization of actuator efficiency and rigid body motion control, historically moving mass in stages could be kept fairly constant over time. Analyses on throughput improvement options, however, show that this trend will no longer hold, primarily due to electromagnetic and power amplifier limitations. To meet future productivity and overlay requirements, moving mass has to be reduced significantly. This will be required to stretch existing 300 mm technology, but in particular to enable future 450 mm generations. Although a potential transfer is still unsure and wafer generation targets remain unchanged by the International Roadmap Committee, is it considered important to assess standards and productivity improvement options for both generations. For the 450 mm generation, stages and overlay systems development are among the key-issues for the 32 nm node and beyond.

Unfortunately, there is not currently a means for the required precision of the short stroke stages to address such issues. In particular, there is not currently a means for nano-precise short stroke stages for actuation.

The principles of the present disclosure provide a means for designing nano-precise short stroke stages for actuation in X, Y and/or θ_{Z}, with sub-50 nm precision and active or passive control in θ_{X}, θ_{Y} and Z as discussed further below.

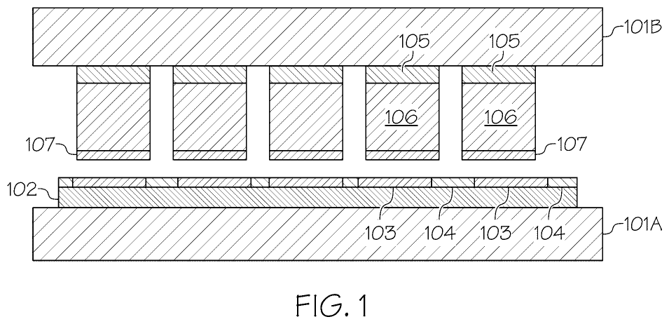

Referring now to the Figures in detail, FIG. 1 illustrates an array of short stroke stages for fine alignment and bonding of two or more, four or more, five or more, six or more, eight or more, ten or more, twelve or more, fifteen or more, twenty or more, thirty or more, fifty or more, or hundred or more dies with respect to one substrate or corresponding number of substrates in accordance with an embodiment of the present disclosure.

As shown in FIG. 1, FIG. 1 illustrates an array of short stroke stages 105, mounted on X-Y positioning stage 101B, where a carrier wafer 102 resides on X-Y positioning stage 101A. Furthermore, as shown in FIG. 1, product dies/substrate 103 reside on carrier wafer 102 along with gap filling material 104 interspersed between product dies/substrate 103.

Additionally, as shown in FIG. 1, short stroke stage modules 105 are located underneath X-Y positioning stage 101B. In one embodiment, chucking modules 106 are attached to short stroke stage modules 105, where chucking modules 106 are used to hold dies 107.

It is noted that the schematic sizes shown in FIG. 1 are not to scale and that the die and substrate alignments are not to scale. In one embodiment, such alignments are performed with sub-50 nm alignment precision.

Furthermore, FIG. 1 illustrates how one or more short stroke stage modules 105 are used to independently align one or more dies 107 to product dies/substrate 103, which are placed on carrier wafer 102 with gap filling material 104 (e.g., silicon oxide) between individual product dies 103. In one embodiment, the stage design is presented in two components: (1) bearing interface between the stator and the mover of the stage, and (2) actuation strategies for the central mover motion. The bearing interfaces and actuation strategies allow control of a combination of 3 or more, 4 or more, 5 or more, 6 or more, 7 or more, 8 or more, 9 or more, or 10 or more of X Y, θ_{Z}, Z, θ_{X}, and θ_{Y} directions of the short-stroke stage.

In one embodiment, one or more of the following bearing methods are used: (1) flexure; and (2) flexure+liquid-film.

In one embodiment, one or more of the following actuation strategies are used: (1) flexure-based actuation; (2) planar motor based actuation—commutative; and (3) planar motor based actuation—non-commutative. It is to be noted that planar motor based actuation, as used herein, refers to electromagnetic actuation. These short stroke stages are compact, and their exemplary form factors in the XY plane include 20 mm×20 mm, 10 mm×10 mm, and 5 mm×5 mm.

It is noted that the term grounded bodies, as used herein, refers to a rigid body being mechanically grounded (not electrical) unless specified otherwise.

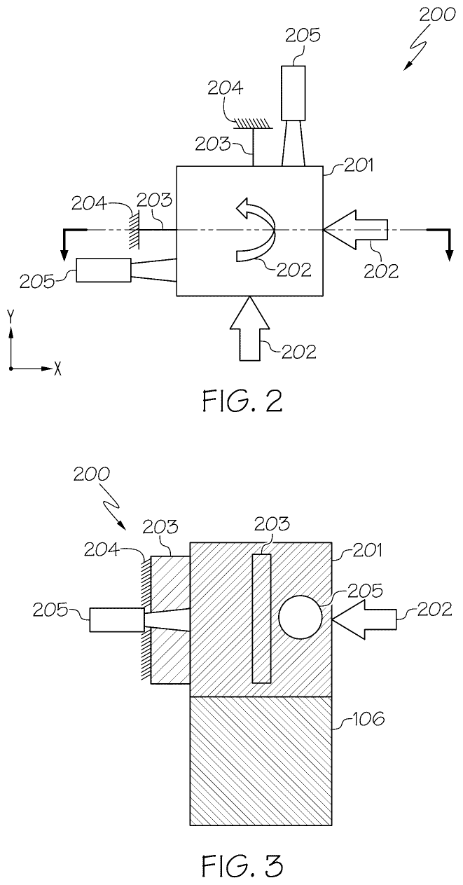

Referring now to FIG. 2, FIG. 2 illustrates the top view of the positioning stage schematics in accordance with an embodiment of the present disclosure.

As shown in FIG. 2, the top view of positioning stage 200 includes a mover 201 and actuators 202 along with flexures 203 and grounded bodies/stator 204. Furthermore, positioning stage 200 includes optional metrology hardware 205.

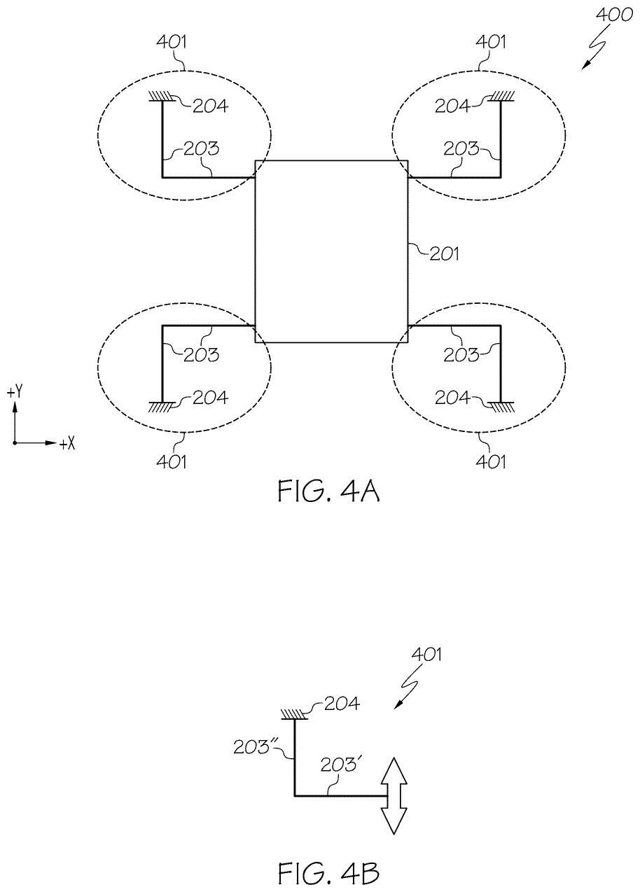

Referring now to FIG. 3, FIG. 3 illustrates the front sectional view of the positioning stage schematics in accordance with an embodiment of the present disclosure.

As shown in FIG. 3, the front sectional view of positioning stage 200 includes chucking module 106.

Referring to FIGS. 2 and 3, the flexure-based design of the stages actuating in X, Y, and θ_{Z} and supported in Z, θ_{X}, and θ_{Y} actively or passively align one or more substrates 103 with respect to one or more substrate/template/wafer/product substrate with nanometer or smaller scale precision. FIGS. 2 and 3 show the general schematics of stage 200 where flexures 203 are designed as bearing interfaces to connect central mover/stage 201 and grounded body (stator) 204 so as to make the movement of mover/stage 201 compliant in desired directions and stiff in other directions.

In one embodiment, one or more of the following components are present to achieve the desired functionality and performance of the positioning stage: (1) in-plane flexures; (2) out-of-plane flexures; (3) passive flexures; (4) actuators; and (5) flexures for preventing parasitic motion, where in-plane flexures, out-of-plane flexures, passive flexures and flexures for preventing parasitic motion are collectively shown in FIGS. 2 and 3 as element 203.

In-plane flexures are used as a bearing interface between grounded body (stator) 204 and mover 201. These flexures provide compliance in in-plane directions, i.e., X, Y, and θ_{Z}, meanwhile supporting mover 201 in the other three directions, i.e., θ_{X}, θ_{Y}, and Z. Out-of-plane flexures are used to transmit motion from actuators 202 to mover 201 as actuators 202 are packed in-plane or out-of-plane according to the overall size and form factor requirements of the stage, which are dictated by the stage application. Passive flexures are the flexures used to provide stage compliance in θ_{X}, θ_{Y}, and Z.

It is noted that the in-plane flexures constitute the bearing interface. Other flexures and mechanisms are presented to ensure proper functioning of the flexures as a bearing interface and are applicable to all the other bearing interfaces.

The following discusses the in-plane flexure mechanisms. In-plane flexures, as used herein, refers to flexures that are designed to enable precise movement of the central stage/mover 201 in the in-plane axes, i.e., X, Y, and θ_{Z}.

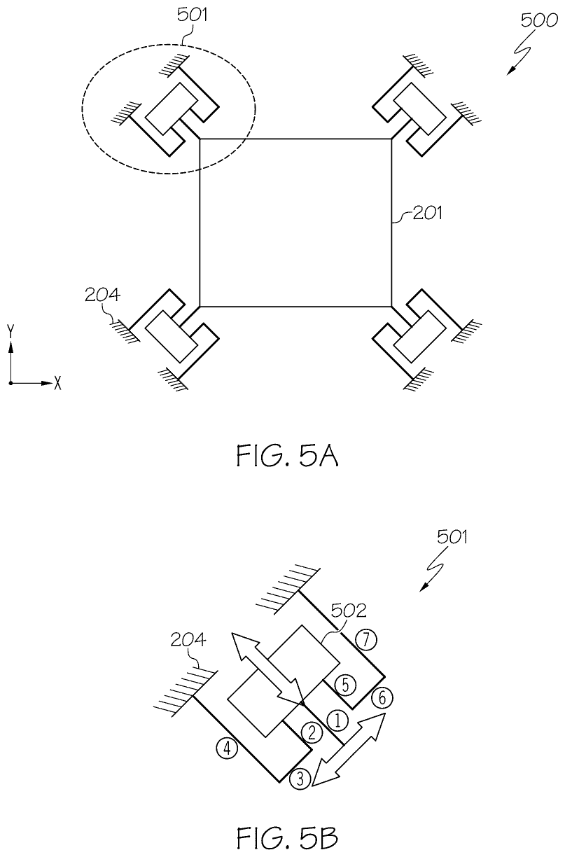

Referring to FIG. 4A, FIG. 4A illustrates an in-plane flexure mechanism 400 in accordance with an embodiment of the present disclosure.

In one embodiment, in-plane flexure mechanism 400 corresponds to a single flexure unit, known as a “crab-leg,” consisting of two flexures 203 arranged serially and orthogonally so that it can allow motion in two directions, which in this case corresponds to the X and Y directions.

Furthermore, FIG. 4A shows a mechanism for in-plane flexure arrangement to make mover 201 compliant in in-plane degrees of freedom, i.e., X, Y, and θ_{Z}. In one embodiment, there are one or more crab-legs 401 along both in-plane axes with an equal number of crab-legs 401 along both the axes.

Referring now to FIG. 4B, FIG. 4B illustrates the direction of motion allowed by a single crab-leg 401 in accordance with an embodiment of the present disclosure.

A crab-leg 401, as used herein, refers to a set of orthogonal flexures 203, such as flexures 203′ and 203″, arranged in series, which allows motion in one direction in-plane and restricts motion in the orthogonal direction in-plane. Flexure 203′ is flexure orthogonal to the axis since the axis of its length and the axis motion are orthogonal. Similarly, flexure 203″ is called “flexure along the axis.”

Referring now to both FIGS. 4A and 4B, in one embodiment, there are one or more crab-legs 401 along both in-plane axes with a varying number of crab-legs 401 along both the axes.

In one embodiment, the length, width, and height of both flexures 203 (e.g., flexures 203′ and 203″) of a single crab-leg 401 are equal which results in equal stiffness imparted by a single crab-leg 401 irrespective of the axes it is placed along. If there are an equal number of such crab-legs 401 along both in-plane axes, stiffness along both axes is equal and the structure is symmetric.

In one embodiment, the length, width, and height of both flexures 203 (e.g., flexures 203′ and 203″) of a single crab-leg 401 vary according to desired stiffness and motion range along a certain direction. Exemplary dimensions for these flexures 203 are shown in Table 1.

TABLE 1
Exemplar Crab-leg Flexure Dimensions

| | | | Flexure 2 (other remaining | | |
|---|---|---|---|---|---|
| Flexure 1 (one of 203′ or 203″) | | | of 203′ or 203″) | | |
| Length | Width | Height | Length | Width | Height |
| (mm) | (mm) | (mm) | (mm) | (mm) | (mm) |
| 10 | 5 | 10 | 4 | 5 | 10 |
| 15 | 3 | 12 | 8 | 7 | 12 |
| 5 | 2 | 10 | 5 | 2 | 10 |

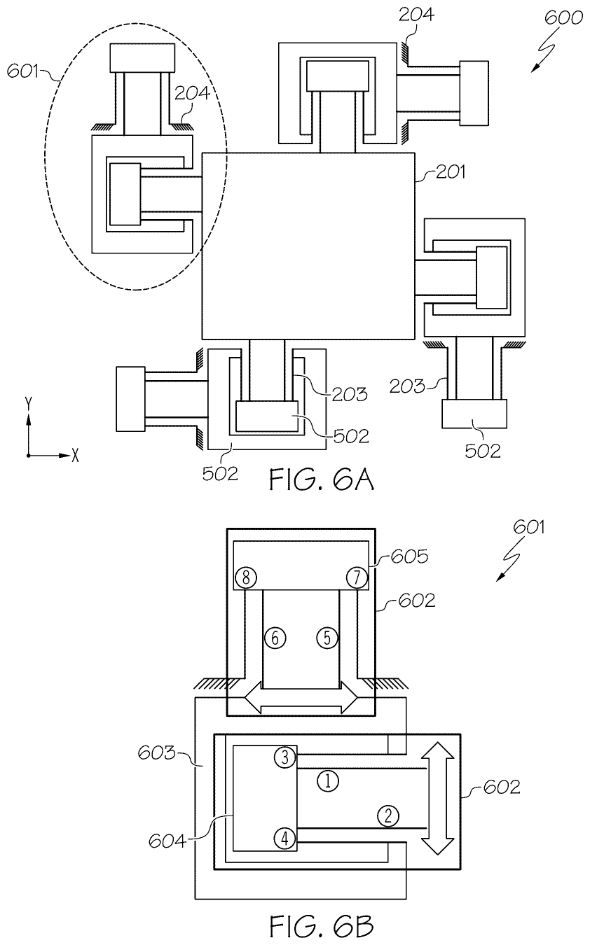

Referring now to FIG. 5A, FIG. 5A illustrates an in-plane flexure mechanism 500 in accordance with an embodiment of the present disclosure.

As shown in FIG. 5A, in-plane flexure mechanism 500 includes cross flexure elements 501 connected to central stage/mover 201. Furthermore, as illustrated in FIG. 5A, cross flexure element 501 includes grounded bodies 204.

In one embodiment, each cross flexure element 501 provides motion in a certain direction, and with an appropriate combination of such cross flexure elements 501 arranged in a certain manner can impart motion in desired directions. In one embodiment, one or more cross flexure elements 501 are present which provide motion to central stage/mover 201 as desired.

Referring now to FIG. 5B, FIG. 5B illustrates the direction of motion of a single cross flexure element 501, including across intermediate body 502, in accordance with an embodiment of the present disclosure.

As shown in FIG. 5B, in one embodiment, cross flexure element 501 is symmetric with respect to the axis of flexure 203 labeled #1, i.e., the dimensions of flexures 203 labeled #2 and #5, flexures 203 labeled #3 and #6, and flexures 203 labeled #4 and #7 are the same.

In one embodiment, cross flexure element 501 is not symmetric with respect to the axis of flexure 203 labeled #1, where the dimensions of one or more of the flexure pairs, i.e., flexures 203 labeled #2 and #5, flexures 203 labeled #3 and #6, and flexures 203 labeled #4 and #7, are different. The dimensions are derived such that the motion direction and motion range is available as desired, while fulfilling the stiffness constraints/requirements.

In one embodiment, one or more of flexures 203 (e.g., flexures 203 labeled #3 and #6) are rigid bodies.

In one embodiment, one or more cross flexure elements 501 are connected such that the angle between flexure 203 labeled #1 of cross flexure element 501 and the edge of central stage/mover 201 at the point of contact (referred to herein as the “contact angle” hereafter) is between 0° and 180°, inclusive of both the bounding angles.

In one embodiment, all cross flexure elements 501 present in mechanism 500 have the same contact angle.

In one embodiment, one or more cross flexure elements 501 present in mechanism 500 have a different contact angle to achieve desired stiffness and motion along a certain axis.

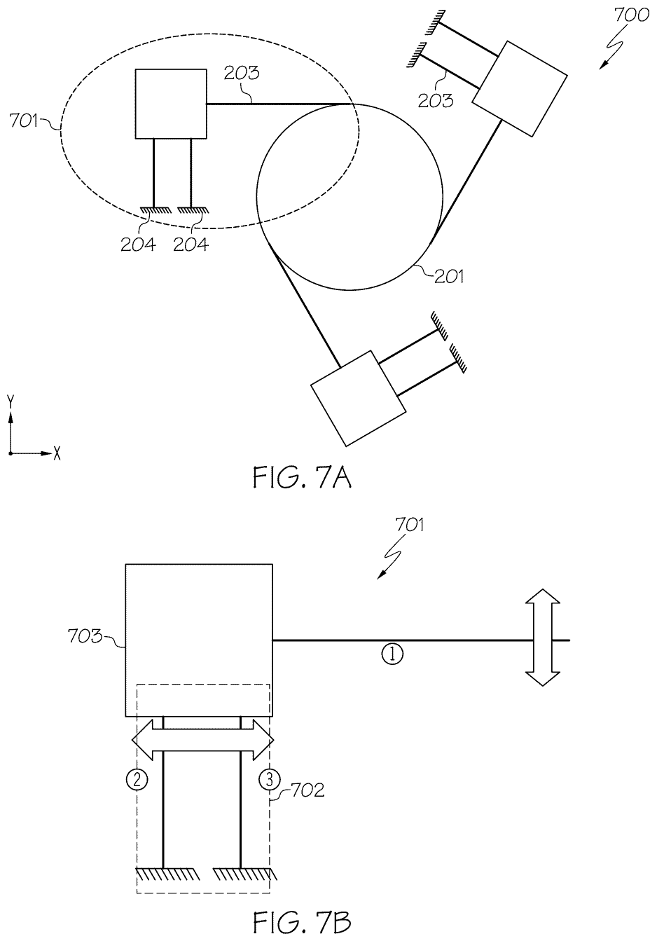

Referring now to FIG. 6A, FIG. 6A illustrates double parallelogram structures 601 arranged serially to provide motion in directions X and Y with a significant motion range in both directions in accordance with an embodiment of the present disclosure.

Furthermore, FIG. 6A shows an exemplary in-plane mechanism 600. In one embodiment, there are one or more double parallelogram elements 601 attached to central stage/mover 201 along both axes. These double parallelogram elements 601 have individual double parallelograms, which provide motion in orthogonal axes.

In one embodiment, there is an equal number of double parallelogram elements 601 along each in-plane axis of central stage/mover 201. If the dimensions of each flexure 203 are the same across all elements, mechanism 600 provides symmetric stiffness and motion range with respect to both in-plane axes.

Referring now to FIG. 6B, FIG. 6B illustrates the structure of a double parallelogram element 601 in accordance with an embodiment of the present disclosure.

As shown in FIG. 6B, double parallelogram element 601 includes double parallelograms 602 connected via an intermediate body 603. Both double parallelograms 602 together form double parallelogram element 601.

In one embodiment, within element 601, the dimensions of flexures 203 labeled #1 and #2, and flexures 203 labeled #3 and #4 are the same, with the dimensions of flexures 203 labeled #3 and #4, and flexures 203 labeled #7 and #8 being the same. This provides uniform stiffness and motion range in both axes of element 601. In one embodiment, flexures 203 labeled #3 and #4 are connected by intermediate body 604. In one embodiment, flexures 203 labeled #5 and #6 and labeled #7 and #8 are connected by intermediate body 605.

In one embodiment, within element 601, the dimensions of flexures 203 labeled #1 and #2, and flexures 203 labeled #3 and #4 are the same, with the dimensions of flexures 203 labeled #3 and #4, and flexures 203 labeled #7 and #8 being different. These dimensions are derived according to desired stiffness and motion range for individual axes of element 601.

In one embodiment, within element 601, the dimensions of flexures 203 labeled #1 and #2, and flexures 203 labeled #3 and #4 are different, with the dimensions of flexures 203 labeled #3 and #4, and flexures 203 labeled #7 and #8 being the same or different. These dimensions are derived according to desired stiffness and motion range for individual axes of element 601.

In one embodiment, the dimensions of all double parallelogram elements 601 attached to central stage/mover 201 are the same offering symmetry in stiffness and motion range in both in-plane axes.

In one embodiment, the dimensions of one or more double parallelogram elements 601 attached to central stage/mover 201 are different. These dimensions are derived according to desired overall stiffness and motion range of mechanism 600 in both in-plane axes.

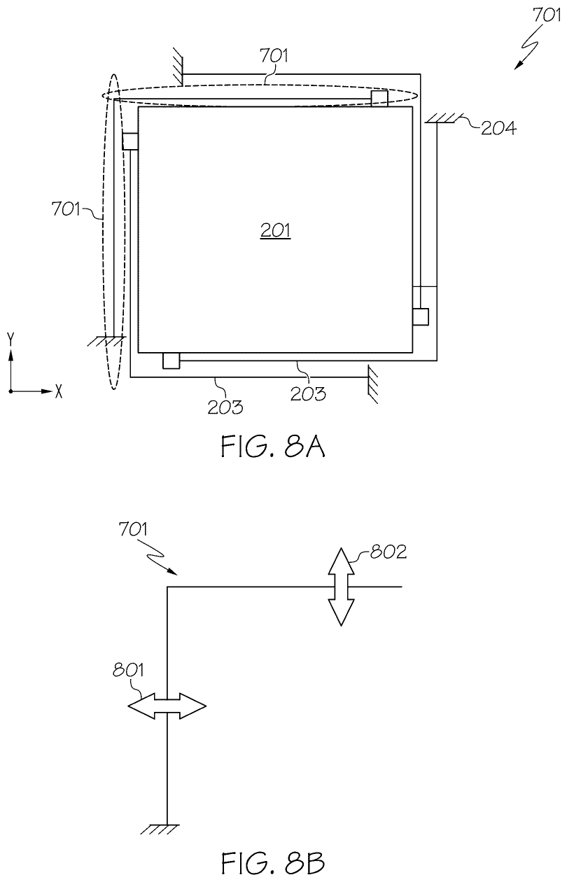

Referring now to FIG. 7A, FIG. 7A illustrates flexure units 701 connected to mover 201 in accordance with an embodiment of the present disclosure.

As shown in FIG. 7A, flexure unit 701 allows motion in two orthogonal directions. With one or more of these flexure units 701 attached to mover 201, flexure unit 701 can have motion in X, Y, and θ_{Z}.

Furthermore, in one embodiment, there are one or more flexure units 701 attached to central stage/mover 201 to enable mover motion in in-plane axes.

Referring now to FIG. 7B, FIG. 7B illustrates the structure of flexure unit 701 of FIG. 7A in accordance with an embodiment of the present disclosure.

In one embodiment, flexure unit 701 includes a flexure 203 that attaches to central stage/mover 201. In one embodiment, flexure unit 701 includes a parallelogram structure 702 or a double parallelogram structure via intermediate body 703 as shown in FIG. 7B.

In one embodiment, all flexure units 701 have a parallelogram structure 702 (flexures 203 labeled #2 and #3) between intermediate body 703 and grounded bodies 204. The dimensions of flexures 203 of parallelogram structure 702 are the same as flexure 203 labeled #1.

In one embodiment, all flexure units 701 have a double parallelogram structure between intermediate body 703 and grounded bodies 204. The dimensions of these flexure units 701 depend on the desired stiffness and motion range in the direction in which this structure enables the motion of the stage.

In one embodiment, at least one or more flexure units 701 have a parallelogram structure 702 between intermediate body 703 and grounded bodies 204, and at least one or more flexure units 701 have a double parallelogram structure between intermediate body 703 and grounded bodies 204.

In one embodiment, all flexure units 701 are structurally similar, and all flexures 203 have the same dimensions across all modules.

In one embodiment, all flexure units 701 are structurally similar and the dimensions of flexures 203 in those flexure units 701 are different. These dimensions depend on the overall stiffness requirements of the mover motion in different axes.

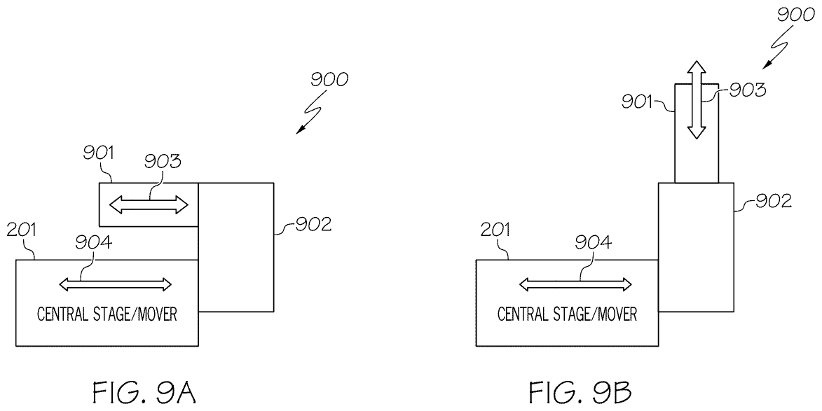

Referring now to FIG. 8A, FIG. 8A illustrates flexure units 701 arranged serially in orthogonal directions to allow the motion of mover 201 in two directions in accordance with an embodiment of the present disclosure.

As shown FIG. 8A, one or more of these flexure units 701 attached to mover 201 provides actuation in the X, Y, and θZ directions.

In one embodiment, one or more flexure units 701 as shown in FIG. 8A are attached to mover 201 and form a bearing interface for mover 201.

Referring now to FIG. 8B, FIG. 8B illustrates the structure of flexure unit 701 of FIG. 8A in accordance with an embodiment of the present disclosure.

In one embodiment, flexure unit 701 consists of two flexures 203 which are orthogonal to each other in a serial fashion in the X-Y plane, and hence provide compliance in both directions (X direction 801 and Y direction 802). Their dimensions are independent of each other and are derived according to the stiffness and motion range requirements.

In one embodiment, one or more flexure units 701 have different dimensions of the same flexures 203 across flexure units 701.

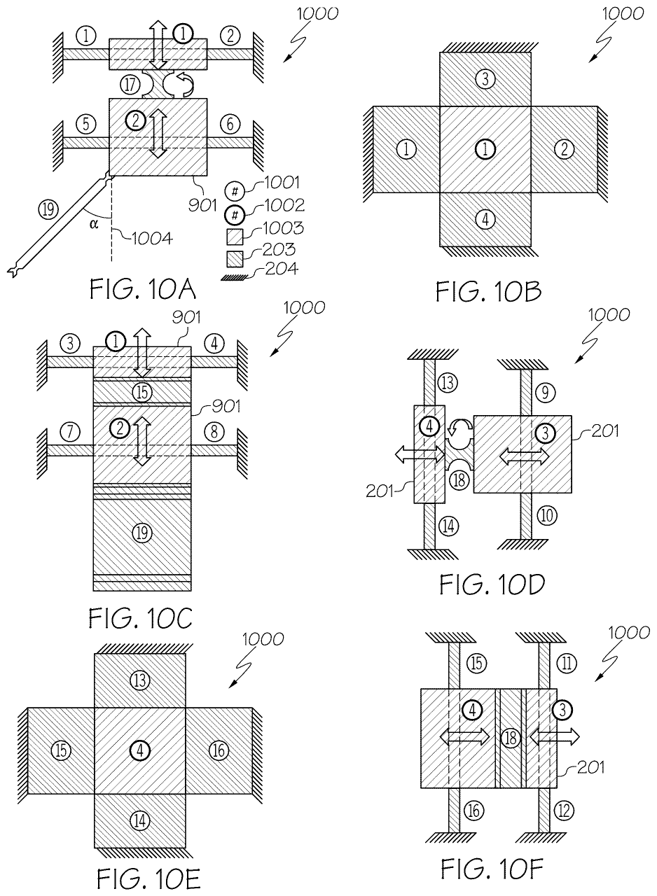

Referring now to FIGS. 9A and 9B, FIG. 9A illustrates an actuator 901 attached along an axis which is out of plane of mover 201 in accordance with an embodiment of the present disclosure. FIG. 9B illustrates actuator 901 attached along an axis which is orthogonal to the axis of the desired motion of mover 201 in accordance with an embodiment of the present disclosure.

FIGS. 9A and 9B illustrate an architecture 900 that allows packaging of the actuators (e.g., actuator 901) away from the point of actuation of the mover (e.g., mover 201) so that flexures 203 for in-plane mechanism and positioning sensors can be efficiently packed.

Furthermore, architecture 900 includes out-of-plane flexures 902, which are flexures designed to transmit the motion (see element 903) from actuators 901 fitted on a different axis than the axis of desired mover motion 904, as shown in FIGS. 9A-9B. Out-of-plane flexures 902 have input blocks, which are directly connected to actuator 901. Furthermore, in one embodiment, out-of-plane flexures 902 have output blocks which are connected directly to central stage/mover 201. The input blocks receive motion 903 from actuators 901 and through the flexure mechanisms, motion 903 gets transmitted to the output block, which directly transfers motion 904 to central stage/mover 201.

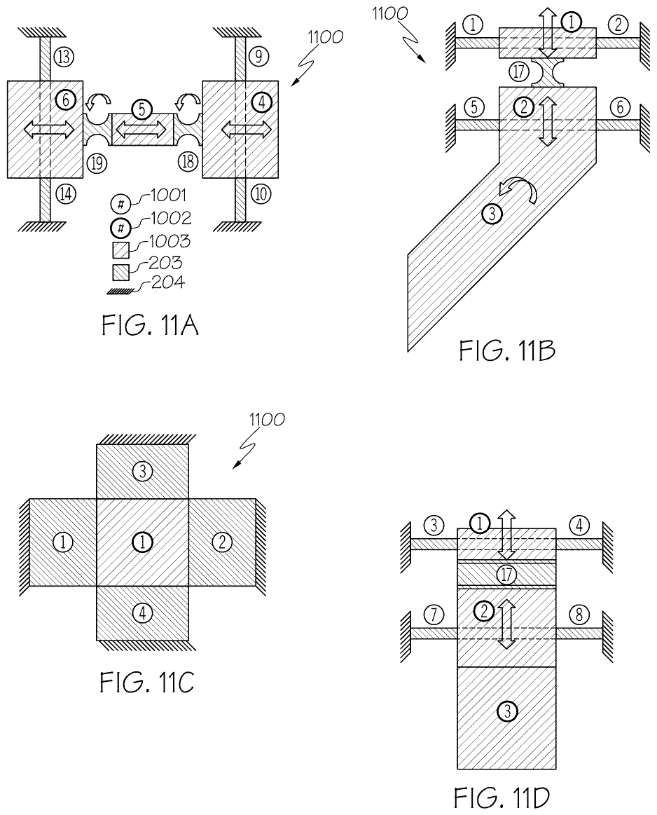

Referring now to FIGS. 10A-10F, FIG. 10A illustrates a double slider out-of-plane mechanism 1000, which is a flexural equivalent of a rigid-body double slider, in accordance with an embodiment of the present disclosure. In one embodiment, double slider out-of-plane mechanism 1000 receives input motion from the actuator packed along the Z-direction and translates the motion to the mover (e.g., mover 201) in the X or Y direction depending on the mechanism's orientation with respect to the mover.

FIG. 10B illustrates a top view of double slider out-of-plane mechanism 1000 in accordance with an embodiment of the present disclosure.

FIG. 10C illustrates a side view of double slider out-of-plane mechanism 1000 in accordance with an embodiment of the present disclosure.

FIG. 10D illustrates another side view of double slider out-of-plane mechanism 1000 in accordance with an embodiment of the present disclosure.

FIG. 10E illustrates an additional side view of the side view of double slider out-of-plane mechanism 1000 of FIG. 10D in accordance with an embodiment of the present disclosure.

Furthermore, FIG. 10F illustrates a top view of the side view of double slider out-of-plane mechanism 1000 of FIG. 10D in accordance with an embodiment of the present disclosure.

For FIGS. 10A-10F, 11A-11I, 13A-13D, 14, 16A-16B, 18C, and 19A-19B, identifiers of flexures 203 are shown by flexure identifiers 1001. For FIGS. 10A-10F, 11A-11I, 13A-13D, 14, 16A-16B, 18C, and 19A-19B, identifiers of the body are shown by body identifiers 1002.

Furthermore, for FIGS. 10A-10F, 11A-11I, 13A-13D, 14, 16A-16B, 18C, and 19A-19B, rigid bodies are shown by rigid body identifiers 1003.

In one embodiment, flexure 203 identified by #19 serves as the main link in mechanism 1000 that transfers the motion from body #2 to body #3. The motion of body #2 is in the direction of actuator 901, whereas, the motion of body #3 is in the direction of the desired motion of mover 201.

In one embodiment, the input block of mechanism 1000 is body #1, with any combination of flexures 203 identified by #1, #2, #3 and #4 to aid the motion of body #1 along a straight line and restrict its motion in other directions. Flexure 203 #17, which is a hinge flexure, facilitates the minimization of parasitic motion transfer to body #2 from body #1.

In one embodiment, body #2 is attached to flexure 203 #19 to transmit the motion to body #3, and to any combination of flexures 203 #5, #6, #7 and #8, which restrict the motion of body #2 in all directions, but one shown in FIGS. 10A-10F.

In one embodiment, body #3 is attached to flexure 203 #19 to receive the motion from body #2, and also to any combination of flexures 203 #9, #10, #11 and #12, which restrict the motion of body #3 in all directions, but one shown in FIGS. 10A-10F.

In one embodiment, body #4 acts as the output block, with any combination of flexures 203 #13, #14, #15 and #16. Flexure 203 #18, which is a hinge flexure, facilitates the minimization of transfer of parasitic motions to body #4 from body #3.

In one embodiment, body #4 is connected directly to mover 201 of the stage or through an intermediate link.

In one embodiment, actuator 901 is directly connected to body #2, which acts as an input block.

In one embodiment, body #3 is directly connected to mover 201, in which case, body #3 is the output block.

In one embodiment, the angle α, which is the angle between flexure 203 #19 and the normal to the mover plane (shown as dotted axis 1004 in FIG. 10A) is between 0° and 90°, inclusive of those two angles.

In one embodiment, one or more number of sets of any combinations of support flexures 203 (flexures (1, 2, 3, 4), (5, 6, 7, 8), (9, 10, 11, 12), and (13, 14, 15, 16)) are used to support the motion of the corresponding bodies according to the stiffness requirements. The dimensions of these flexures 203 depend on stiffness and range of motion requirements.

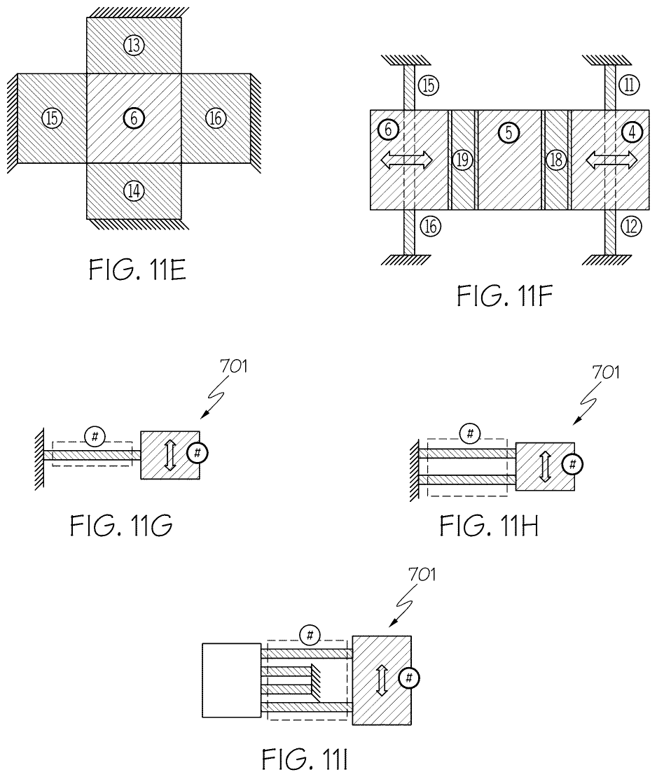

Referring to FIGS. 11A-11I, FIG. 11A illustrates the out-of-plane flexure mechanism 1100 in accordance with an embodiment of the present disclosure.

FIG. 11B illustrates a front view of the out-of-plane flexure mechanism 1100 in accordance with an embodiment of the present disclosure.

FIG. 11C illustrates a top view of the front view of the out-of-plane flexure mechanism 1100 of FIG. 11B in accordance with an embodiment of the present disclosure.

FIG. 11D illustrates a side view of the front view of the out-of-plane flexure mechanism 1100 of FIG. 11B in accordance with an embodiment of the present disclosure.

FIG. 11E illustrates a side view of the out-of-plane flexure mechanism 1100 in accordance with an embodiment of the present disclosure.

FIG. 11F illustrates a top view of the out-of-plane flexure mechanism 1100 in accordance with an embodiment of the present disclosure.

FIG. 11G illustrates the structure of flexure unit 701 as a single flexure in accordance with an embodiment of the present disclosure.

FIG. 11H illustrates the structure of flexure unit 701 as a parallelogram structure in accordance with an embodiment of the present disclosure.

FIG. 11I illustrates the structure of flexure unit 701 as a double parallelogram structure in accordance with an embodiment of the present disclosure.

Furthermore, as shown in FIGS. 11A-11I, flexures 203 #1-#16 are “support” flexure units 701. The structure of such support flexure units 701 have different versions as shown in FIGS. 11G-11I as discussed above.

In one embodiment, out-of-plane flexure mechanism 1100 receives input motion from actuator 901 packed along the Z-direction and translates the motion to mover 201 in the X or Y direction depending on the orientation of mechanism 1100 with respect to mover 201.

In one embodiment, body #1 is attached to actuator 901, and hence body #1 acts as an input block. Body #1 is attached to any combination of support flexure units #1, #2, #3 and #4. The structure of these support flexure units can be either a single flexure, parallelogram structure or a double parallelogram structure as illustrated in FIGS. 11G-11I, respectively. The structure of these support flexure units 701 and their dimensions are independent of each other and are designed according to the stiffness and motion range requirements of mechanism 1100.

In one embodiment, body #2 transfers its motion to body #3, which acts as an intermediate link to transfer the motion orthogonally. Body #2 is connected to grounded bodies 204 via any combination of support flexures #5, #6, #7 and #8. Their structure and dimensions, which are independent of each other, are derived according to the stiffness and motion range requirements.

In one embodiment, flexure hinge #17 acts as an interface between bodies #1 and #2 to minimize the parasitics in motion transfer from bodies #1 to #2 and minimize the transmission of shear forces onto the actuator due to slight rotations of body #2.

In one embodiment, body #4 receives the motion from body #3 in the axis of the desired motion of central stage/mover 201. Body #3 is connected to any combination of support flexure structures #9, #10, #11 and #12. Their structure and dimensions, which are independent of each other, are derived according to the stiffness and motion range requirements.

In one embodiment, flexural hinge #18 receives the motion from body #4 and transfers it to the structure attached to it forward. This hinge acts as an interface for minimization of transmission of parasitic motion due to slight rotations of body #4.

In one embodiment, body #5 receives the motion from flexural hinge #18 and transfers it to flexural hinge #19.

In one embodiment, flexural hinge #19 receives motion from body #5 and transfers the motion to body #6. This hinge acts as an interface to minimize the transmission of parasitics from body #5 to body #6 due to slight rotations of body #6.

In one embodiment, body #6 is connected directly to mover 201, hence acting as an output block. Body #6 is connected to any combination of support flexure structures #13, #14, #15 and #16. Their structure and dimensions, which are independent of each other, are derived according to the stiffness and motion range requirements.

It is noted that the top view of body #2 with flexures #5, #6, #7 and #8 of FIG. 11C is similar to the top view of body #1. Furthermore, it is noted that the side view of body #3 with flexures #9, #10, #11 and #12 of FIG. 11E is similar to the top view of body #1.

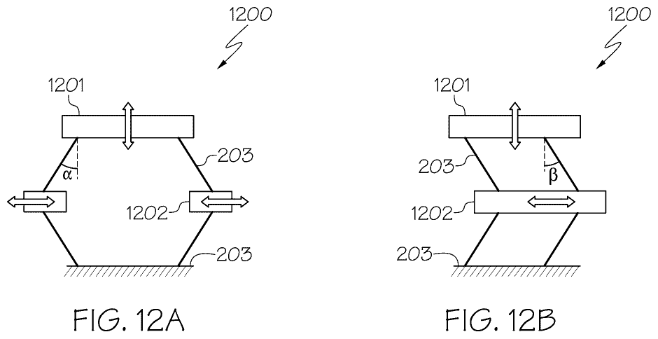

FIG. 12A illustrates an exemplary out-of-plane flexure mechanism 1200 where flexures 203 diverge from the input block to two separate output blocks in accordance with an embodiment of the present disclosure. FIG. 12B illustrates an alternative embodiment of out-of-plane flexure mechanism 1200 where flexures 203 diverge from the input block to a single output block in accordance with an embodiment of the present disclosure.

Referring to FIGS. 12A-12B, out-of-plane flexure mechanism 1200 receives input motion from actuator 901 packed along the Z-direction and translates the motion to mover 201 in the X or Y direction depending on mechanism's 1200 orientation with respect to mover 201.

In one embodiment, flexures 203 diverge from input block 1201 to two separate bodies, both acting as output blocks 1202, which are connected to central stage/mover 201 as shown in FIG. 12A.

In one embodiment, the angle α, as shown in FIG. 12A, ranges between 0° and 90°, including both the angles.

In one embodiment, flexures 203 run parallel to each other from input block 1201 to a single output block 1202 as shown in FIG. 12B.

In one embodiment, the angle ß, as shown in FIG. 12B, ranges between 0° and 90°, including both the angles.

In one embodiment, the dimensions of flexures 203 and the angles between flexures 203 and their respective body of origin are independent and are derived according to the stiffness and motion range requirements.

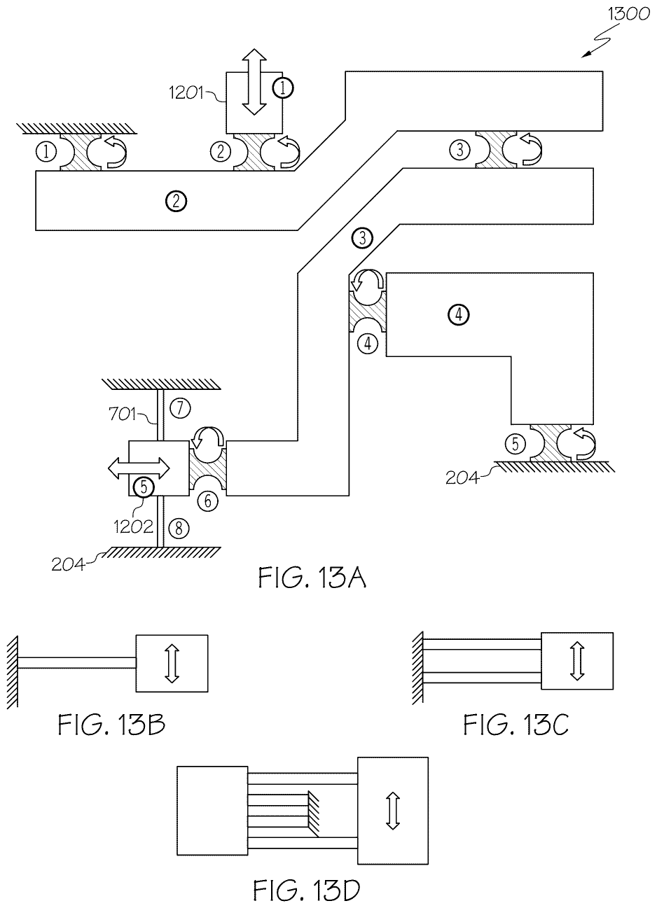

FIG. 13A illustrates an out-of-plane flexure straight line mechanism 1300 in accordance with an embodiment of the present disclosure.

Referring to FIG. 13A, in one embodiment, block #1 is connected to actuator 901, hence acting as input block 1201.

In one embodiment, body #2 acts as a rigid link that is actuated by input block 1201. Through hinges #1 and #2, its rotation is enabled when it receives motion from input block 1201.

In one embodiment, hinge #3 receives the rotational motion from body #2 and transmits the motion to body #3.

In one embodiment, body #3 acts an intermediate link and its rotation is enabled via hinges #3, #4 and #6.

In one embodiment, body #4 acts an intermediate link between ground body 204 and body #3, and is hinged at two locations, hinge #4 and #6, which enable its rotation. The purpose of body #4 is to restrict the motion of body #3 in such a way that at hinge #6, there is a desirable rotation movement, which can then be converted into linear motion in the desired direction.

In one embodiment, body #5 receives the motion from body #3 via hinge #6. The motion of body #5 in a linear direction is enabled by support flexures 203 #7 and #8, which can be combined to form a flexure unit 701, which may structured as a single flexure, a parallelogram structure or a double parallelogram structure as shown in FIGS. 13B-13D, respectively. FIG. 13B illustrates flexure unit 701 that is used in FIG. 13A as a single flexure in accordance with an embodiment of the present disclosure. FIG. 13C illustrates flexure unit 701 that is used in FIG. 13A as a parallelogram structure in accordance with an embodiment of the present disclosure. FIG. 13D illustrates flexure unit 701 that is used in FIG. 13A as a double parallelogram structure in accordance with an embodiment of the present disclosure.

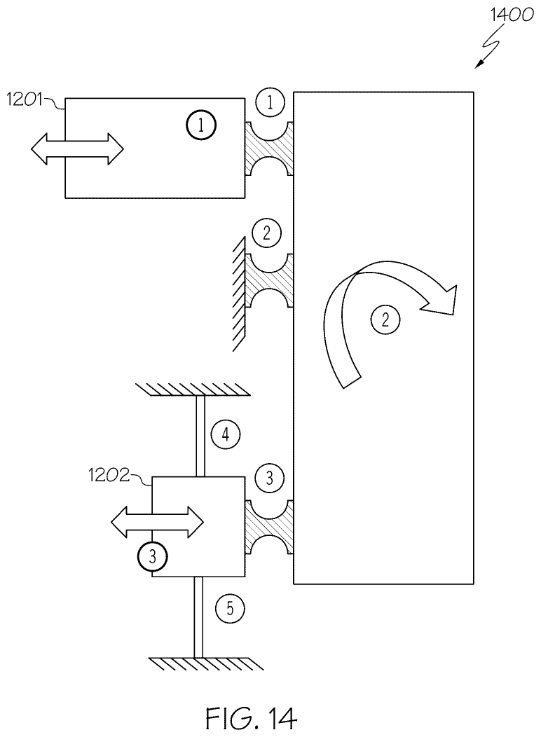

Referring now to FIG. 14, FIG. 14 illustrates a lever type out-of-plane mechanism 1400 in accordance with an embodiment of the present disclosure.

In one embodiment, lever type out-of-plane mechanism 1400 receives input motion from actuator 901 packed along the X or Y direction and translates the motion to mover 201 in the X or Y direction depending on the orientation of mechanism 1400 with respect to mover 201.

In one embodiment, mechanism 1400 is the flexure version of a type 1 lever. In one embodiment, body #2 acts as a type 1 lever.

In one embodiment, the effort side of the lever is attached to body #1 through hinge #1. In this case, body #1 acts as input block 1201 for mechanism 1400.

In one embodiment, the load side of the lever is attached to body #3 through hinge #3, in which case, body #3 acts as output block 1202 of mechanism 1400.

In one embodiment, body #3 is attached to support flexures 203 #4 and/or #5, which can be combined to form a flexure unit 701, which may structured as a single flexure, a parallelogram structure or a double parallelogram structure as shown in FIGS. 13B-13D, respectively. By utilizing such a structure, the rotational motion transmitted from body #2 to body #3 is minimized. Furthermore, by utilizing such a structure, body #3 is able to transmit a linear motion to central stage/mover 201.

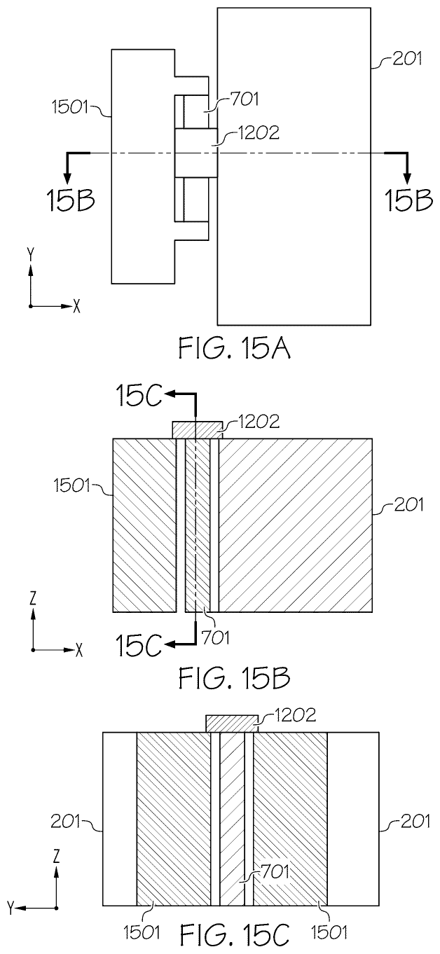

Referring now to FIGS. 15A-15C, FIG. 15A illustrates a top view of the support flexure unit 701 with a stator in accordance with an embodiment of the present disclosure. FIG. 15B illustrates a cross-sectional front view of the support flexure unit 701 with a stator in accordance with an embodiment of the present disclosure. FIG. 15C illustrates a cross-sectional side view of the support flexure unit 701 with a stator in accordance with an embodiment of the present disclosure.

In one embodiment, the arrangement of support flexure unit 701 in-plane as shown in FIGS. 15A-15C eliminates the parasitic motion of output blocks 1202 of the out-of-plane flexure mechanisms described above. Furthermore, such an arrangement results in an efficient connection between mover 201, the in-plane mechanism and the out-of-plane mechanism.

In one embodiment, the support flexure unit 701 of the out-of-plane flexure mechanisms 1100, 1200 are attached to a stator wall 1501 as shown in FIGS. 15A-15C. In one embodiment, stator wall 1501 and these support flexure units 701 are grounded with respect to mover 201, and therefore, units 701 are placed between mover 201 and stator wall 1501 to provide convenience in packing flexures 203 efficiently.

In one embodiment, output block 1202 of the out-of-plane flexure mechanism 1100, 1200 is placed on top of flexure support unit 701 which is placed between stator wall 1501 and mover 201 of the stage.

In one embodiment, support flexure units 701 are single flexures, parallelogram structures or double parallelogram structures. The structure and flexure dimensions of these units 701 are independent of each other and are designed according to the stiffness and motion range requirement.

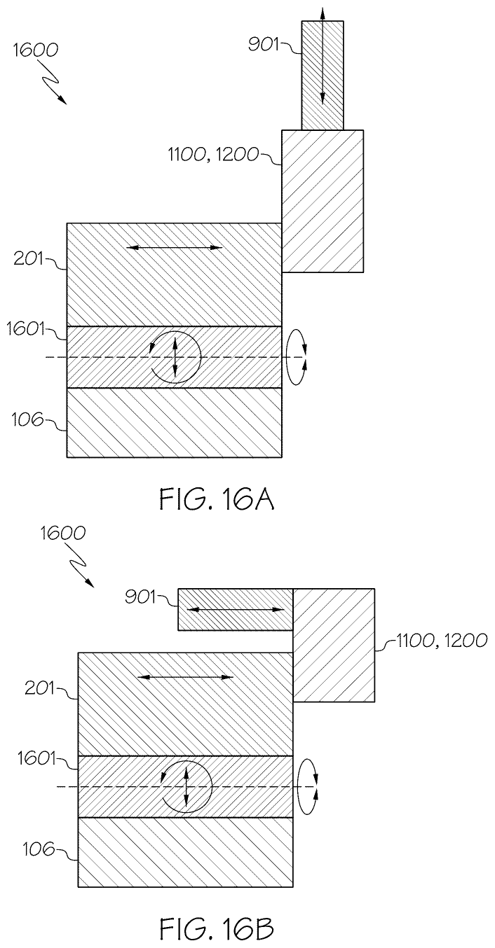

A discussion regarding passive flexures is now deemed appropriate. Referring to FIGS. 16A-16B, FIG. 16A illustrates a schematic of a mechanism 1600 utilizing a passive flexure mechanism 1601 in conjunction with an actuator (e.g., actuator 901) that actuates in a vertical motion in accordance with an embodiment of the present disclosure. FIG. 16B illustrates a schematic of a mechanism 1600 utilizing a passive flexure mechanism 1601 in conjunction with an actuator (e.g., actuator 901) that actuates in a horizontal motion in accordance with an embodiment of the present disclosure.

As shown in FIGS. 16A-16B, passive flexure mechanism 1601 located on top of chucking modules 106 are designed to provide compliance to mover 201 in Z, θ_{X}, and θ_{Y}. Such passive flexure mechanisms 1601 are not designed for active control/actuation along such directions. Hence, they are referred to herein as “passive” flexure mechanisms 1601.

In one embodiment, stage/mover 201 is actuated in X, Y, and θ_{Z}, but not actively actuated in the rest of the three degrees of freedom. Hence, passive flexures, such as passive flexure mechanisms 1601, are designed to add compliance in Z, θ_{X}, and θ_{Y} so that stage/mover 201 can handle external forces in these directions without causing any hindrance in X, Y, and θ_{Z}. Since passive flexure mechanisms 1601 are only for supporting stage/mover 201 for handling external forces, the flexures of passive flexure mechanisms 1601 are not actuated, and hence, the name “passive” flexures.

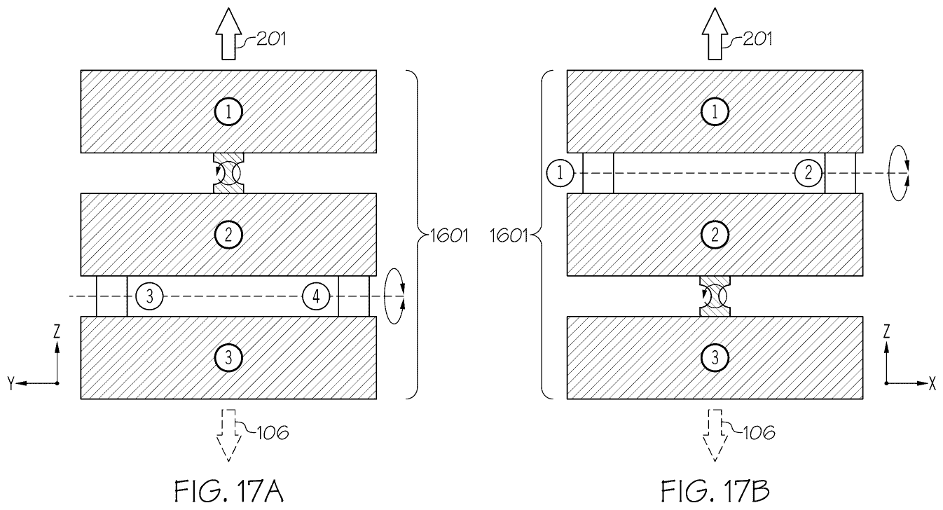

Referring now to FIGS. 17A-17B, FIG. 17A illustrates the side view of passive flexure mechanism 1601 in accordance with an embodiment of the present disclosure. FIG. 17B illustrates the front view of passive flexure mechanism 1601 of FIG. 17A in accordance with an embodiment of the present disclosure.

As illustrated in FIGS. 17A-17B, passive flexure mechanism 1601 utilizes flexural hinges to provide compliance in θ_{X} and θ_{Y}.

In one embodiment, body #1 connects to central stage/mover 201 and connects to body #2 on the other side via flexural hinges #1 and #2 as shown in FIG. 17B. These hinges provide compliance to body #2 in θ_{X}.

In one embodiment, body #2 is connected to body #3 via two flexural hinges #3 and #4 as shown in FIG. 17A. These hinges provide compliance to body #3 in θ_{Y}.

In one embodiment, body #3 is connected to chucking module 106. As a result, chucking module 106 has compliance in θ_{X} and θ_{Y}, which can resist external forces acting on the die without hindering the working of central stage/mover 201.

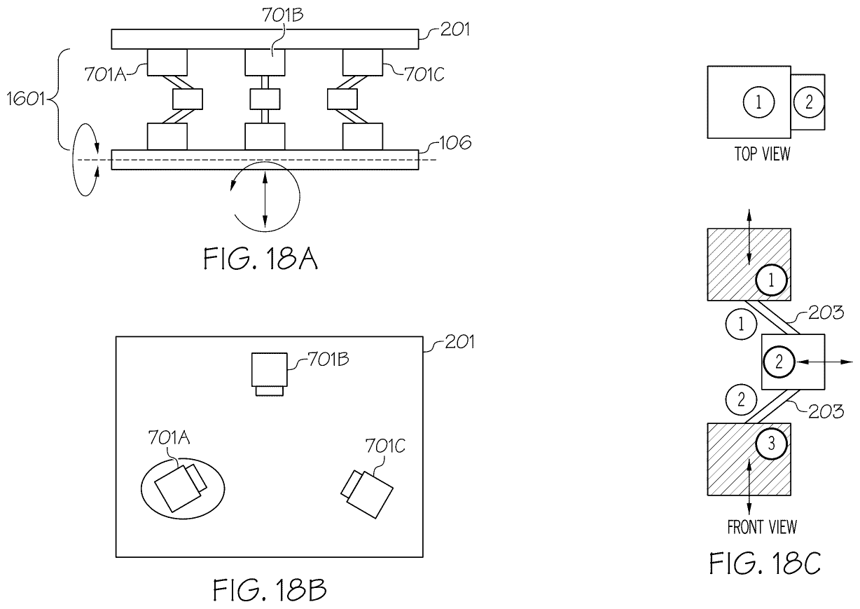

Referring now to FIG. 18A, FIG. 18A illustrates the front view of passive flexure mechanism 1601 in accordance with an embodiment of the present disclosure.

In one embodiment, passive flexure mechanism 1601 is constructed in a manner that allows compliance in the Z direction. In one embodiment, a set of three flexure units 701 (labeled as 701A-701C) is constructed, which allows passive flexure mechanism 1601 to be complaint in Z direction.

In one embodiment, a set of three flexure units 701 (labeled as 701A-701C in FIG. 18A) assembled as shown in FIG. 18A collectively enable compliance in Z, θ_{X}, and θ_{Y}. Depending on the external forces acting on chucking module 106, these units will undergo displacement along Z direction accordingly.

FIG. 18B illustrates the top view of passive flexure mechanism 1601 of FIG. 18A in accordance with an embodiment of the present disclosure.

FIG. 18C illustrates an expanded form of flexure unit 701A of passive flexure mechanism 1601 of FIG. 18A in accordance with an embodiment of the present disclosure. FIG. 18C illustrates both the top view and front view of flexure unit 701A.

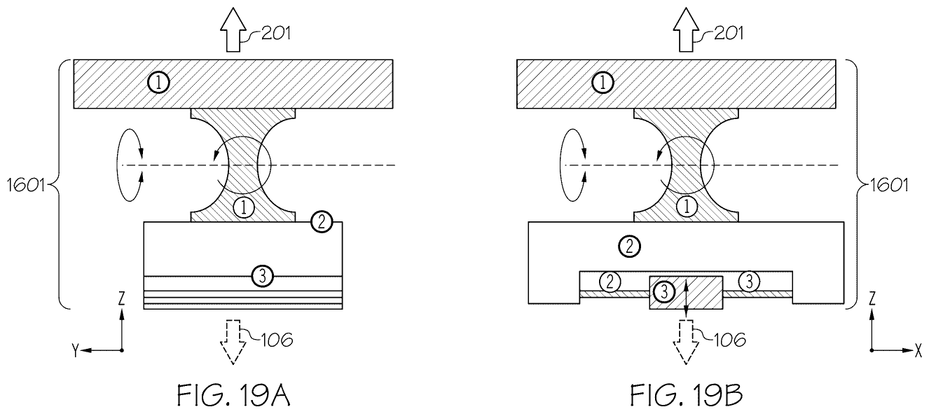

Referring now to FIGS. 19A and 19B, FIG. 19A illustrates a side view of passive flexure mechanism 1601 utilizing a hinge flexure in accordance with an embodiment of the present disclosure. FIG. 19B illustrates a front view of passive flexure mechanism 1601 utilizing a hinge flexure in accordance with an embodiment of the present disclosure.

In one embodiment, body #1 is attached to central stage/mover 201 as shown in FIGS. 19A-19B. On the other side of body #1, there is a two degrees of freedom flexural hinge (hinge #1 in FIG. 19A-19B), which can provide compliance in both θ_{X} and θ_{Y}.

In one embodiment, the flexural hinge #1 is attached to body #2 which acts as an intermediate body between flexural hinge #1 and flexures 203 #2 and #3 as shown in FIG. 19B. Body #2 also acts as a ground for flexures 203 #2 and #3.

In one embodiment, flexures 203 #2 and #3 are connected to body #3 and supported via flexures 203 #2 and #3 which restrict the degrees of freedom of body #3 in all directions but one, i.e., Z direction.

As shown in FIGS. 9A-9B, actuators 901 are packed along the Z axis, or along the X axis or Y axis, but in a plane which is offset by a certain distance from the plane of central stage/mover 201. Packing actuators 901 in this way offers sufficient space to include complex and densely packed flexure mechanisms in-plane, with a smaller footprint in the XY plane.

In one embodiment, one or more actuators 901 are Piezoelectric Actuators (PZTs). PZTs have actuation precision in nm scale, which can enable the stage actuation precision in nm.

In one embodiment, one or more actuators 901 are Voice Coil Motors (VCMs). VCMs have nm scale actuation precision and can impart high actuation forces. With precise current control, the VCMs can actuate flexure mechanisms precisely, and as a result, central stage/mover 201 can be actuated at nm scale precision.

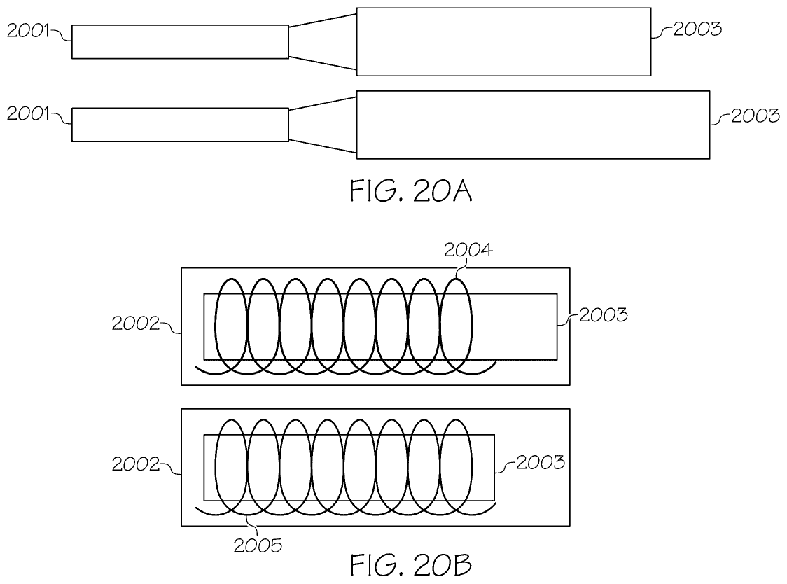

Referring now to FIGS. 20A-20B, FIG. 20A illustrates thermal action performed through a power light emitting diode (LED) 2001 in accordance with an embodiment of the present disclosure. FIG. 20B illustrates thermal action performed through an actively controlled heat exchanger 2002 in accordance with an embodiment of the present disclosure.

In one embodiment, one or more actuators 901 are thermal actuators. These actuators are structures made out of a material with high co-efficient of thermal expansion. A heat source, such as a high power LED 2001 or heat exchanger 2002, can be used to expand/contract the actuation bar 2003 as shown in FIGS. 20A-20B. Due to expansion/contraction, actuation bar 2003 imparts force on the out-of-plane flexure mechanism, which actuates central stage/mover 201. Heat exchanger 2002 may be convection-based, radiation-based, or both.

Referring to FIG. 20B, coil 2004 in heat exchanger 2002 indicates that the temperature is high and actuation bar 2003 is in the expanded state; whereas, coil 2005 indicates that the temperature is low and actuation bar 2003 is in the contracted state.

In one embodiment, one or more actuators 901 are direct drive DC linear motors.

In one embodiment, one or more actuators 901 are screw-drive based actuators that have a rotational motor as an actuator.

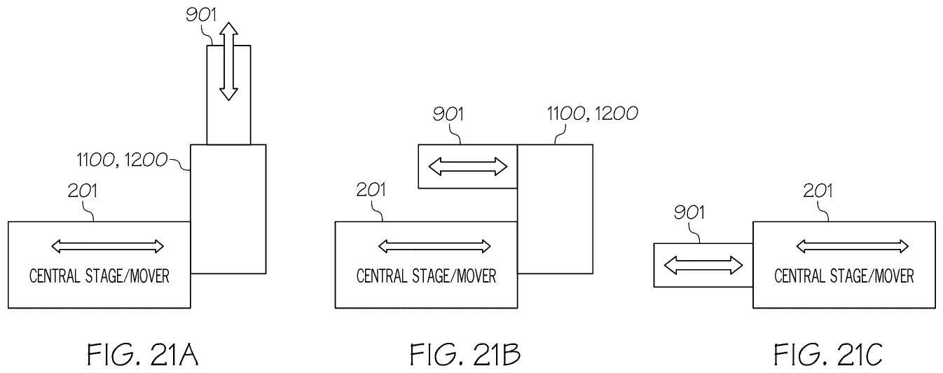

Referring now to FIGS. 21A-21C, FIG. 21A illustrates an architecture for packaging actuators 901 in accordance with an embodiment of the present disclosure. FIG. 21B illustrates an alternative architecture for packaging actuators 901 in accordance with an embodiment of the present disclosure. FIG. 21C illustrates a further alternative architecture for packaging actuators 901 in accordance with an embodiment of the present disclosure.

The architecture for packaging actuators 901 as shown in FIGS. 21A-21C allows for compact footprint of the necessary in-plane flexure mechanisms 400, 500.

In one embodiment, one or more actuators 901 are packed along the Z-axis as illustrated in FIG. 21A. In one embodiment, out-of-plane flexure mechanism 1100, 1200 converts the actuator motion along the Z-axis to the stage movement along the X-axis or Y-axis.

In one embodiment, one or more actuators 901 are packed along the X or Y axis but in a plane offset from the mover plane. In one embodiment, out-of-plane flexure mechanism 1100, 1200 transmits the motion of actuator 901 in an offset plane to the mover plane.

In one embodiment, one or more actuators 901 are packed such that their motion is in the plane of mover 201. This arrangement gives an advantage of a small number of parts in the assembly and minimizes possible parasitics introduced by out-of-plane flexure mechanisms 1100, 1200.

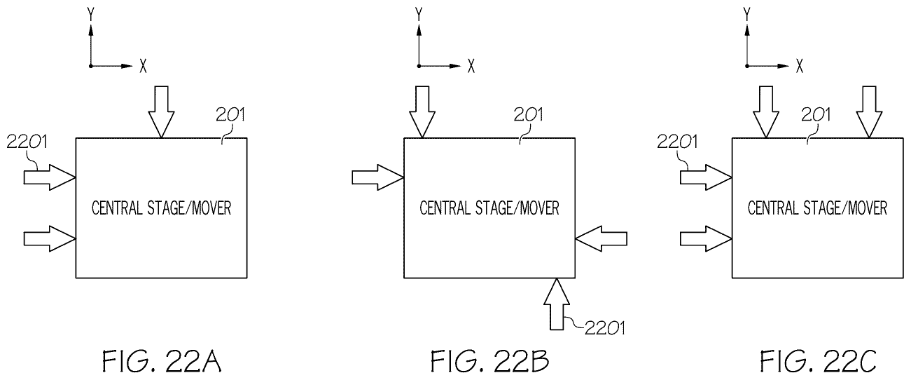

Referring now to FIGS. 22A-22C, FIG. 22A illustrates an actuator-stage interface placement architecture in accordance with an embodiment of the present disclosure. FIG. 22B illustrates an alternative actuator-stage interface placement architecture in accordance with an embodiment of the present disclosure. FIG. 22C illustrates a further alternative actuator-stage interface placement architecture in accordance with an embodiment of the present disclosure.

As shown in FIGS. 22A-22C, actuator-stage interfaces 2201 apply force (in other words, impart motion) on the stage to achieve motion in desired directions.

In one embodiment, two actuator-stage interfaces 2201 are used to actuate in the X direction, and 1 for actuation in the Y direction, as illustrated in FIG. 22A. Additionally, the 2 actuator-stage interfaces 2201 along the X direction can also provide actuation in θ_{Z}, where the amount of actuation and/or direction are not same for both interfaces 2201.

In one embodiment, one actuator-stage interface 2201 is attached to mover 201 on each of its 4 sides, as illustrated in FIG. 22B. Each interface 2201 is at a certain offset from the center of the edge of mover 201 to which it connects. Through appropriate kinematics of the system, desired motion can be achieved in all 3 desired axes, i.e., X, Y, and θ_{Z}.

In one embodiment, two actuator-stage interfaces 2201 are connected to one edge of mover 201 for actuating along the X direction and the same arrangement is connected to an orthogonal edge for actuation along the Y direction, as illustrated in FIG. 22C. With appropriate actuation forces and their directions through these actuator-stage interfaces, desired actuation in X, Y, and θ_{Z} can be achieved.

As shown in FIGS. 22A-22C, actuator-stage interfaces 2201 can be arranged in different directions in-plane in multiple configurations. These interfaces 2201 are mechanisms rigidly connected to central stage/mover 201.

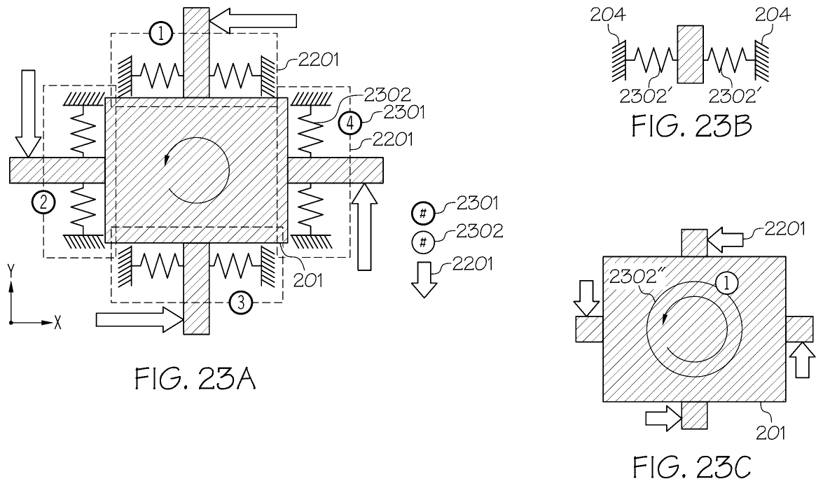

Referring to FIG. 23A, FIG. 23A illustrates a mechanism for θ_{Z} actuation in accordance with an embodiment of the present disclosure.

In one embodiment, actuation in θZ is achieved by adding a rotation stage in series with the XY stage. FIG. 23A illustrates an exemplary design of one such serial mechanism. In one embodiment, one or more stage-ground interfaces 2301 are attached to central stage/mover 201 at its edge. Each stage-ground interface 2301 can have dimensions of their elements independent of each other, and are designed according to the stiffness requirements of the application.

In one embodiment, stage-ground interface 2301 consists of one or more springs 2302, such as linear springs 2302′, to provide restoring forces in the direction opposite to that of the forces applied by actuator-stage interface 2201. An illustration of springs 2302 corresponding to linear springs 2302′ is provided in FIG. 23B in accordance with an embodiment of the present disclosure.

One or more of these springs 2302 are helical tension springs, helical compression springs, leaf springs or flexures 203. An illustration of spring 2302 corresponding to a torsional spring 2302″ is provided in FIG. 23C in accordance with an embodiment of the present disclosure.

Referring to FIGS. 23A-23C, in one embodiment, one or more actuator-stage interfaces 2201 are included to apply actuation force as shown in FIGS. 23A-23C. Since these forces are at a certain distance away from the mover's center of mass, they create a torque along the Z direction, consequently actuating the stage in the θ_{Z} direction. These actuator-stage interfaces 2201 are either the output blocks (e.g., output blocks 1202) of the out-of-plane flexure mechanisms (e.g., out-of-plane flexure mechanisms 1100, 1200), or actuators 901 themselves if these actuators 901 are packed in the same plane as mover 102.

In one embodiment, stage-ground interface 2301 consists of a torsional spring 2302″ as shown in FIG. 23C, whose axis is along the Z direction. In such a configuration, torsional spring 2302″ provides restoring/resistance torque in the Z direction.

In one embodiment, one or more stage-ground interfaces 2301 with one or more linear springs 2302′ are attached to central stage/mover 201 along with stage-ground interface 2301 with torsional spring 2302″.

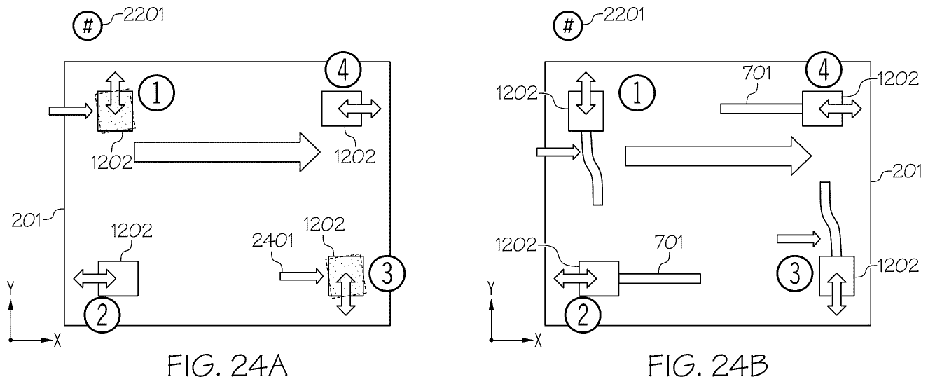

Referring to FIGS. 24A and 24B, FIG. 24A illustrates actuator stability without in-plane support flexure units for actuator stabilization in accordance with an embodiment of the present disclosure. FIG. 24B illustrates actuator stability with in-plane support flexure units for actuator stabilization in accordance with an embodiment of the present disclosure.

In one embodiment, in-plane support flexure units 701 (structured similarly as flexure units 701) are attached to output blocks 1202 of the out-of-plane mechanisms (e.g., out-of-plane mechanisms 1100, 1200) (which serve as actuator-stage interface 2201) so that the out-of-plane mechanisms have compliance in the direction orthogonal to their actuation direction. This is to protect the out-of-plane mechanism assembly from the forces acting on these mechanisms when mover 201 is actuated in a direction orthogonal to their actuation direction. For instance, output blocks 1202 #2 and #4 actuate mover 201 along the X direction and when they actuate, forces action on output blocks 1202 #1 and #3, which can harm the corresponding out-of-plane mechanism assemblies, as shown in FIG. 24B. The support flexure units 701 absorb those forces and the out-of-plane mechanism assemblies corresponding to output blocks 1202 #1 and #3 remain intact as shown in FIG. 24B.

As illustrated in FIG. 24A, output blocks 1202 #1 and #3 become deformed due to the force when there are no in-plane support flexure units for actuator stabilization as shown in FIG. 24A.

Furthermore, as shown in FIGS. 24A-24B, mover 201 moves to the X direction when actuated in the X direction.

Additionally, FIGS. 24A-24B illustrate the forces acting on actuator stage interfaces 2201 in the Y direction (see element 2401) when stage 201 is actuated in the X direction.

As shown in FIGS. 24A-24B, if the stage is actuated in X (for instance), actuator-stage interface 2201 in the Y direction would undergo forces as that can get transmitted to various components of the out-of-plane flexure mechanisms (e.g., out-of-plane mechanisms 1100, 1200) and ultimately to the actuator (e.g., actuator 901) in absence of the in-plane support flexure units (e.g., support flexure units 701) for actuator stabilization. These forces can even lead to mechanical failure of various components of the out-of-plane flexure mechanism (e.g., out-of-plane flexure mechanism 1100, 1200). But, if these support flexure mechanisms (e.g., support flexure units 701) are present, these flexures 203 provide compliance in the direction of mover actuation, and absorb the forces produced by mover actuation and prevent them from transmitting to sensitive components of the out-of-plane mechanism.

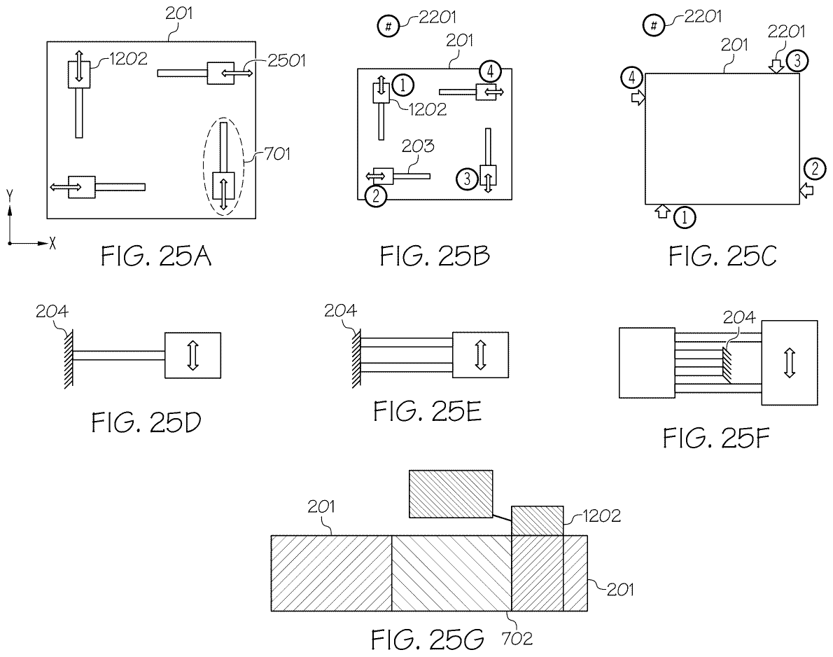

Referring to FIG. 25A, FIG. 25A illustrates a mover (e.g., mover 201) connected with output blocks 1202 of out-of-plane flexure mechanisms (e.g., out-of-plane flexure mechanisms 1100, 1200) in accordance with an embodiment of the present disclosure. Furthermore, FIG. 25A illustrates the direction of motion (see element 2501) of output blocks 1202 of out-of-plane flexure mechanisms.

FIG. 25B illustrates the layout of mover 201 with flexures 203 for actuator stability in accordance with an embodiment of the present disclosure.

FIG. 25C illustrates the corresponding schematic of the actuator-stage interface 2201 in accordance with an embodiment of the present disclosure.

Additionally, support flexure unit 701 of mover 201 may correspond to one of three different structures as shown in FIGS. 25D-25F. FIG. 25D illustrates support flexure unit 701 as a single flexure in accordance with an embodiment of the present disclosure. FIG. 25E illustrates support flexure unit 701 as a parallelogram structure in accordance with an embodiment of the present disclosure. FIG. 25F illustrates support flexure unit 701 as a double parallelogram structure in accordance with an embodiment of the present disclosure. The structure and flexure sizes of support flexure units 701 are independent of each other and are designed according to the stiffness and motion range requirements of the mechanism. Since these flexure units 701 are connected to central stage/mover 201, grounded bodies 204 shown in FIGS. 25D-25F represent the connection with central stage/mover 201.

A sectional view of support flexure units 701 is shown in FIG. 25G in accordance with an embodiment of the present disclosure.

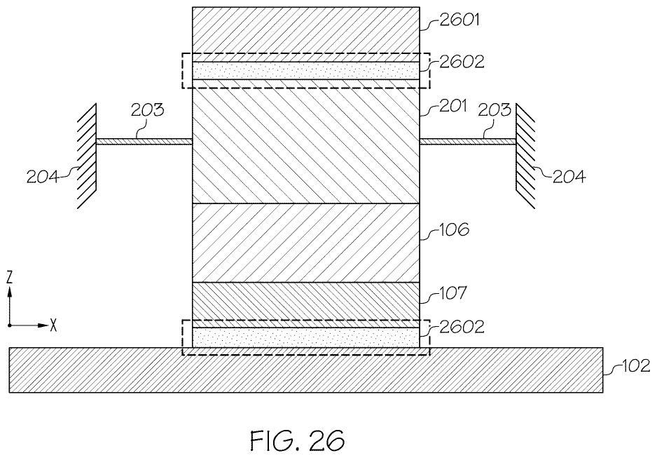

Referring to FIG. 26, FIG. 26 illustrates a flexure and liquid bearing interface in accordance with an embodiment of the present disclosure.

FIG. 26 shows a schematic of an exemplary design of the stage with bearing type flexure+liquid. In one embodiment, mover 201 is attached to one or more in-plane flexure mechanisms (e.g., in-plane flexure mechanisms 400, 500) discussed above. These flexures 203 provide support to mover 201 along the Z direction and are complaint along X, Y, and θ_{Z}.

In one embodiment, stator 2601 is above or below mover 201 to provide a surface to store a thin film of liquid. This liquid film has the appropriate thickness to possess a high amount of capillary force to hold together the two surfaces around it, i.e., stator 2601 and mover 201. The advantage of this film is that it can hold mover 201 along the Z direction with respect to stator 2601 while providing extreme compliance in the X and Y directions. Furthermore, it provides resistance to parasitic motion of mover 201 in θ_{X}, θ_{Y}, and Z. This helps in reducing actuation errors in the stage and hence the precision is greatly improved.

In one embodiment, chucking module 106 for chucking a die 107, which is attached to mover 201, where the opposite side of mover 201 is in contact with liquid film from liquid layer 2602, which lies between mover 201 and stator 2601.

In one embodiment, there is liquid layer 2602 between die 107 and wafer 102, which also has a high amount of capillary force to hold die 107 and the surface of wafer 102 together. In one embodiment, liquid layer 2602 provides the same functionality of supporting mover 201 in the Z direction and preventing parasitic motion of die 107 (and eventually mover 201) with respect to wafer 102 in θ_{X}, θ_{Y}, and Z.

In one embodiment, liquid layer 2602 provides support in Z, θ_{X}, and θ_{Y} which helps in preventing the transmission of parasitic motion of mover 201 to die 107 and simultaneously protects the external forces acting on die 107 to mover 201.

The following discusses various actuation strategies. In particular, the following describes actuation architectures developed to work with the previously discussed bearing interfaces. These actuation architectures are designed considering the space constraints imposed by the bearing interfaces, structural stiffness, motion range requirements, nm-scale precision, and resistance to parasitic motion.

One type of actuation strategy is utilizing flexure-based actuation, which has been previously discussed. For example, exemplary architectures for packing actuators 901 or actuator-stage interfaces 2201 with in-plane flexures 203 has been previously discussed. Furthermore, exemplary orientation and placement of actuator-stage interfaces 2201 has been previously discussed. Finally, additional mechanisms needed for preventing detrimental forces of actuation of stage from transmitting to actuators 901 packed for orthogonal movement to the direction of actuation at any given time has been previously discussed.

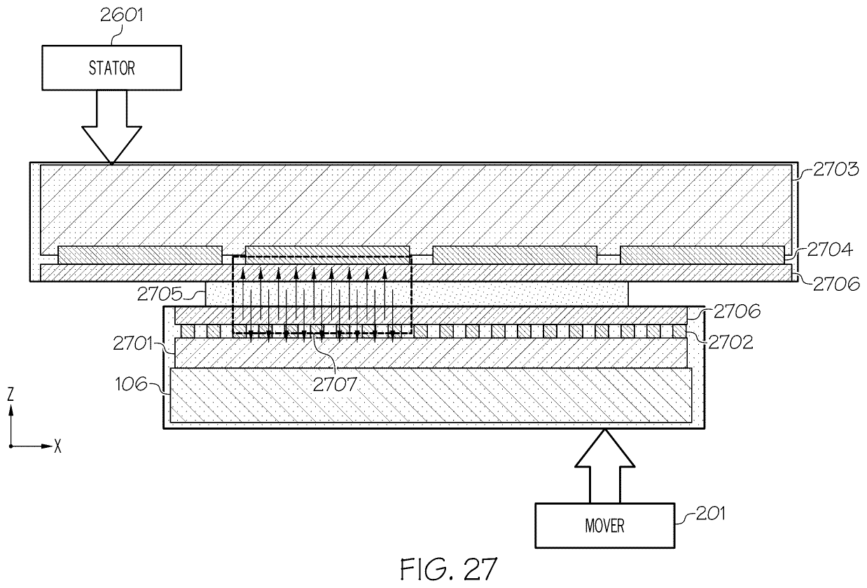

Another type of actuation strategy is commutative planar motor-based actuation discussed below in connection with FIG. 27.

FIG. 27 illustrates a commutative planar motor-based nano-precise positioning stage in accordance with an embodiment of the present disclosure.

As shown in FIG. 27, chucking module 106 includes a magnetic array holder plate 2701 holding a permanent magnet array 2702. Furthermore, FIG. 27 illustrates a thermally stable PCB (printed circuit board) 2703 with inductive elements 2704. Additionally, FIG. 27 illustrates a thin liquid film 2705 between glass wafers 2706 (for interfacing). In one embodiment, liquid film 2705 is water. Furthermore, FIG. 27 illustrates a magnetic field interaction 2707 between inductive elements 2704 and permanent magnet array 2702.

In one embodiment, a coil array and magnet array 2702 produce electromagnetic and magnetic fields which interact with each other to produce actuation force. Accurate control of current flowing through the coils can result in precise control of actuation forces and resultantly, precise control of actuation along X, Y, and θ_{Z}.

In one embodiment, the design of the planar motor-based nano-precise positioning stage of FIG. 27 is based on the electromagnetic actuation of mover 201, which provides precise positioning of the stage.

In one embodiment, several inductive elements 2704 are laid out in a planar fashion and an appropriate amount of current is passed through these elements to generate a magnetic field around them. On an offset and parallel plane, an array of permanent magnets is laid out such that its magnetic field interacts (see element 2707) with the electromagnetic field of inductive elements 2704, and a resultant force is generated which can be used to actuate the plane which is free to move with respect to the plane that has been mechanically grounded.

In one embodiment, the body with inductive elements 2704 is mover 201 and the body with the magnet array is stator 2601.

In one embodiment, the body with magnet array 2702 is mover 201 and the body with inductive elements 2704 is stator 2601.

In one embodiment, one or more of the following components/sub-systems are included in the designing of the planar motor based positioning stage: magnet array 2702, coil array, control architecture, and magnet array fabrication.

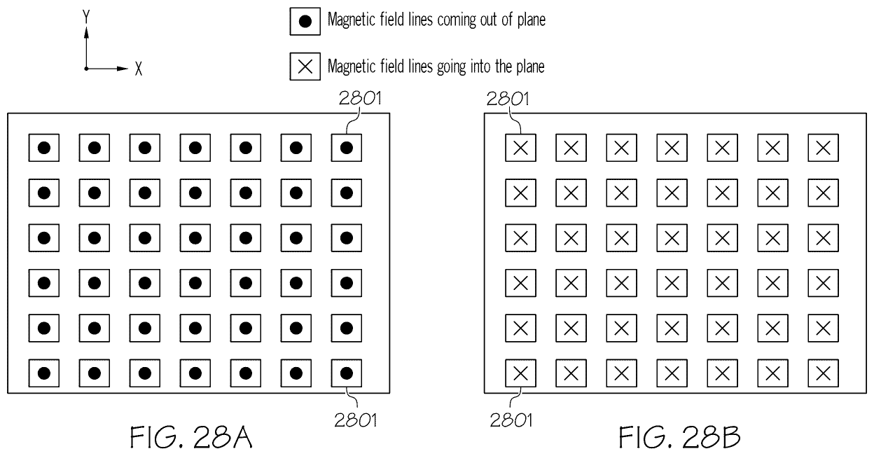

A discussion regarding magnet array 2702 is provided below. Referring now to FIGS. 28A-28B, FIG. 28A illustrates a top view of magnetic field lines coming out of plane from magnet array 2702 in accordance with an embodiment of the present disclosure. FIG. 28B illustrates a top view of magnetic field lines going into the plane from magnet array 2702 in accordance with an embodiment of the present disclosure.

As illustrated in FIGS. 28A-28B, magnets 2801 are arranged in a unidirectional fashion where all magnets 2801 have either north or south pole facing towards the coil array.

Furthermore, FIGS. 28A-28B show an exemplary pattern of an array of permanent magnets 2801. In this arrangement, all magnets 2801 in the array are oriented in a similar fashion. In one embodiment, all magnets 2801 are arranged in such a way that the magnetic field lines from these magnets come out of plane, when viewed from the top, as shown in FIG. 28A.

In one embodiment, all magnets 2801 are arranged in such a way that the magnetic field lines from these magnets 2801 go into the plane, when viewed from the top, as shown in FIG. 28B.

In one embodiment, the pitch of the magnet array of magnets 2801 in the X and Y directions depend on the pole pitch requirement of the overall mechanism for actuation, which includes dependency on coil array, coil pattern, control architecture and magnet array fabrication.

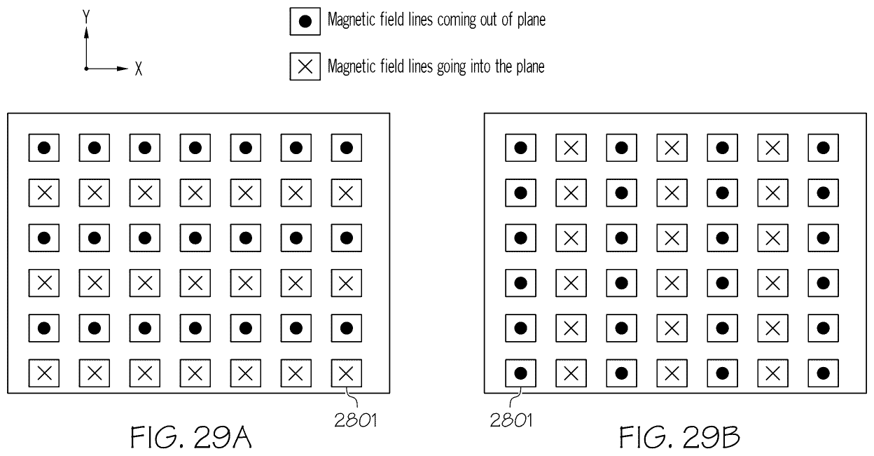

Referring now to FIGS. 29A-29B, FIG. 29A illustrates a top view of an array of magnets 2801 in a first arrangement in a manner that north and south poles alternatively face the coil array in accordance with an embodiment of the present disclosure. FIG. 29B illustrates a top view of an array of magnets 2801 in a second arrangement in a manner that north and south poles alternatively face the coil array in accordance with an embodiment of the present disclosure.

As shown in FIGS. 29A-29B, the alternation of the north and south poles are in one direction only, either along the X or Y direction.

In one embodiment, the polarity of magnets 2801 alternates in one direction while it remains the same in the other direction (out of X and Y directions). This gives an alternating Z-magnetic field in the direction along which magnetic polarity is alternating.

In one embodiment, the polarity of magnets 2801 in the array is the same along the X axis but alternating along Y axis.

In one embodiment, the polarity of magnets 2801 in the array is the same along the Y axis but alternating along the X axis.

In one embodiment, the pitch of magnets 2801 along the X and Y direction in the array depend on precision requirements and the coil array structure.

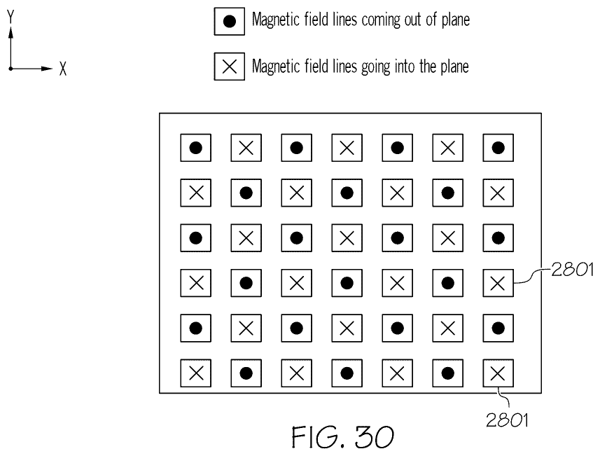

Referring now to FIG. 30, FIG. 30 is a top view of magnets 2801 arranged in such a way that north and south poles alternatively face the coil array in accordance with an embodiment of the present disclosure.

In one embodiment, such an alternation is in two directions, namely the X and Y directions.

Furthermore, FIG. 30 illustrates that when viewed from the top, the polarity of magnets 2801 in the array alternates on both the X and Y axis, which provides an alternating Z-magnetic field along both the X and Y directions.

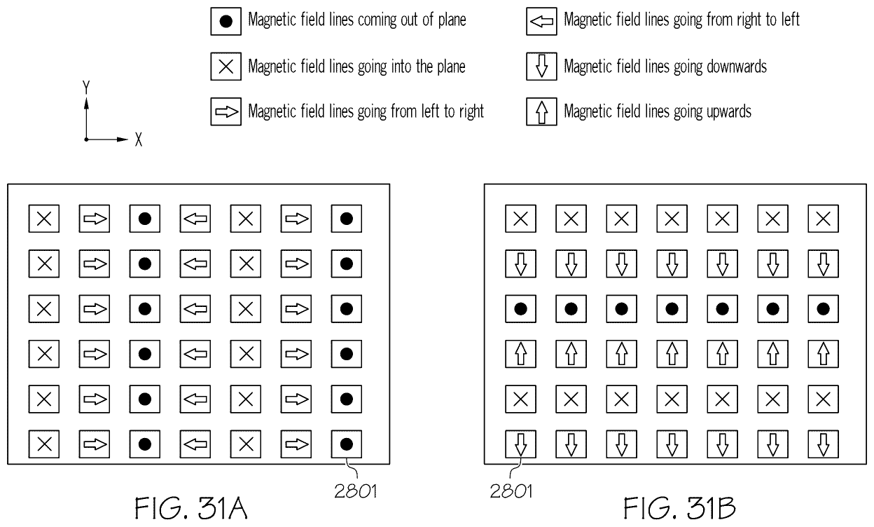

Referring now to FIGS. 31A-31B, FIG. 31A illustrates a top view of an array of magnets 2801 in a first arrangement in a one-dimensional Halbach array in accordance with an embodiment of the present disclosure. FIG. 31B illustrates a top view of an array of magnets 2801 in a second arrangement in a one-dimensional Halbach array in accordance with an embodiment of the present disclosure.

In one embodiment, magnets 2801 are arranged in such a way that the magnetic field lines appear to be rotating along an axis when viewed from the side. This arrangement is known as the Halbach array. This array magnifies the magnetic field intensity of the array of magnets 2801 on the side of the plane of the array and weakens the other side. The stronger side faces the direction towards which the coils are located so that the effective use of the magnetic field intensity of magnets 2801 can be maximized to produce larger actuation forces with relatively smaller currents in the coil.

In one embodiment, the Halbach array is formed along one axis, either X or Y, whereas, the array is identical or alternating along the other axis.

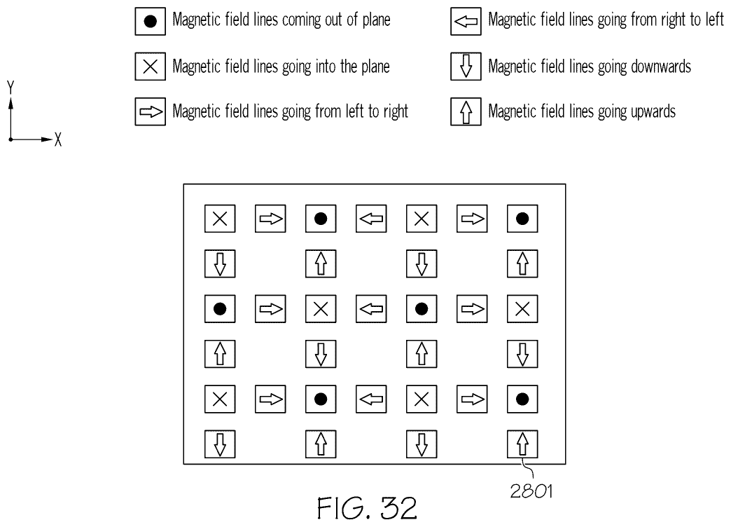

FIG. 32 illustrates a top view of an array of magnets 2801 in a two-dimensional Halbach array in accordance with an embodiment of the present disclosure.

Referring to FIG. 32, in one embodiment, the Halbach array is formed along both the X and Y axes. By such an arrangement, the stronger side of the array of magnets 2801 is further strengthened giving the ability to generate more actuation force.

A discussion regarding the coil array in the design of the planar motor based positioning stage is provided below.

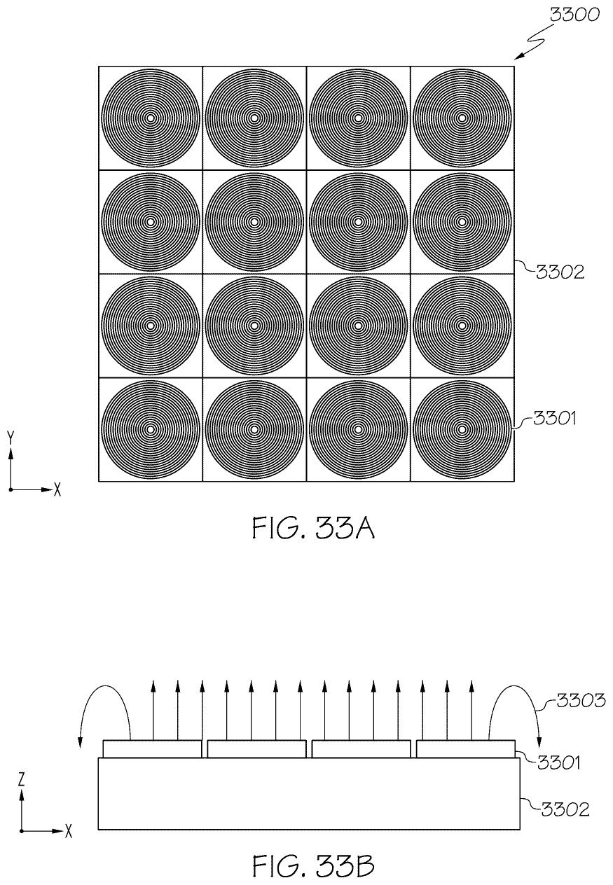

Referring to FIG. 33A, FIG. 33A illustrates a coil array 3300, where each coil 3301 of coil array 3300 is a planar spiral, in accordance with an embodiment of the present disclosure.

Furthermore, as shown in FIG. 33A, coil array 3300 is housed in a thermally stable PCB (printed circuit board) 3302.

Referring to FIG. 33B, FIG. 33B illustrates the magnetic field 3303 produced by current carrying coils 3301 in accordance with an embodiment of the present disclosure.

In one embodiment, each coil 3301 is formed by depositing several spirals of copper on a planar surface. These spirals, when carrying current, produce a magnetic field 3303 with which the magnetic field of the magnet arrays can interact to produce actuation force. In one embodiment, the dimensions of each spiral of coil 3301 and the pitch of the spiral coil array 3300 are designed by keeping in mind the load, the desired actuation precision, the magnet array, and current carrying capacity of the copper traces.

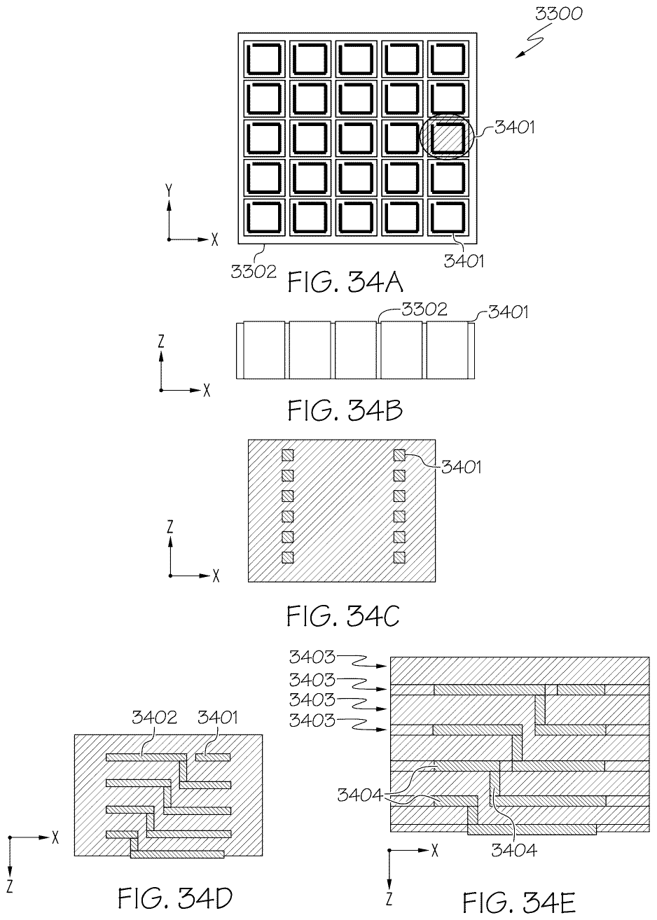

Referring now to FIG. 34A, FIG. 34A illustrates a coil array 3300, where each coil 3401 of coil array 3300 is a helix, in accordance with an embodiment of the present disclosure.

In one embodiment, coils 3401 are of the helical shape as shown in FIG. 34A. The helix perimeter is the perimeter of the cross section of coil 3401.

Referring to FIG. 34B, FIG. 34B illustrates a cross-section of coil array 3300 of FIG. 34A in accordance with an embodiment of the present disclosure.

Referring to FIGS. 34C-34D, FIG. 34C illustrates the cross-sectional front view of coil 3401 in accordance with an embodiment of the present disclosure. FIG. 34D illustrates the cross-sectional inverted back view of coil 3401 in accordance with an embodiment of the present disclosure.

In the cross-sectional views of FIGS. 34C-34D, it can be seen that copper traces 3402 of the coil run through the PCB (printed circuit board) 3302. Due to practical fabrication considerations, a perfect helix may not be possible. Hence, copper traces 3402 change planes in a step manner at a certain location designated for that particular plane. Since the point of change of plane for t copper traces 3402 is different for each plane, no overlap of copper traces 3402 of two or more turns occurs.

In one embodiment, the point of change of plane for copper traces 3402 for each loop is anywhere along the helix perimeter.

Referring to FIG. 34E, FIG. 34E illustrates the layer-by-layer fabrication of helical coil 3401 in accordance with an embodiment of the present disclosure.

In one embodiment, the helix geometry is sliced into multiple layers 3403 and is fabricated in a layer-by-layer fashion by depositing copper 3404 on each layer, eventually forming the shape of a helix.

In one embodiment, the shape of the helix perimeter is any two-dimensional closed polygon.

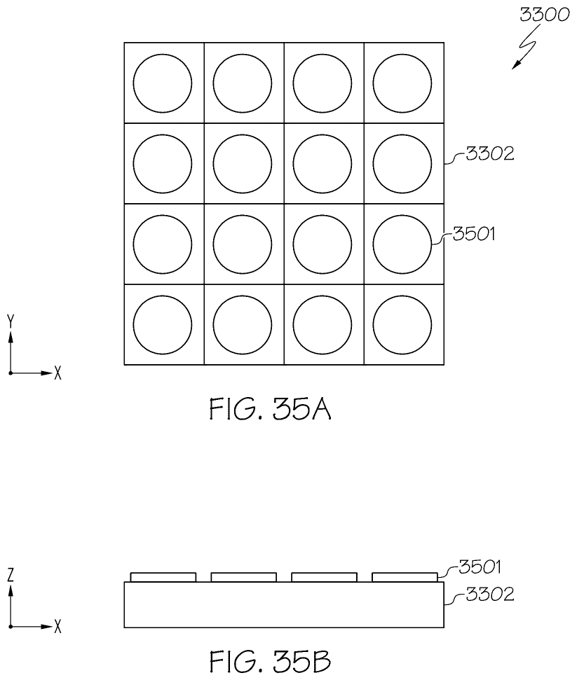

Referring to FIG. 35A, FIG. 35A illustrates a coil array 3300, where each coil 3501 of coil array 3300 is a closed polygon, with sharp corners or rounded corners, in accordance with an embodiment of the present disclosure.

Referring to FIG. 35B, FIG. 35B illustrates a front view of FIG. 35A in accordance with an embodiment of the present disclosure.

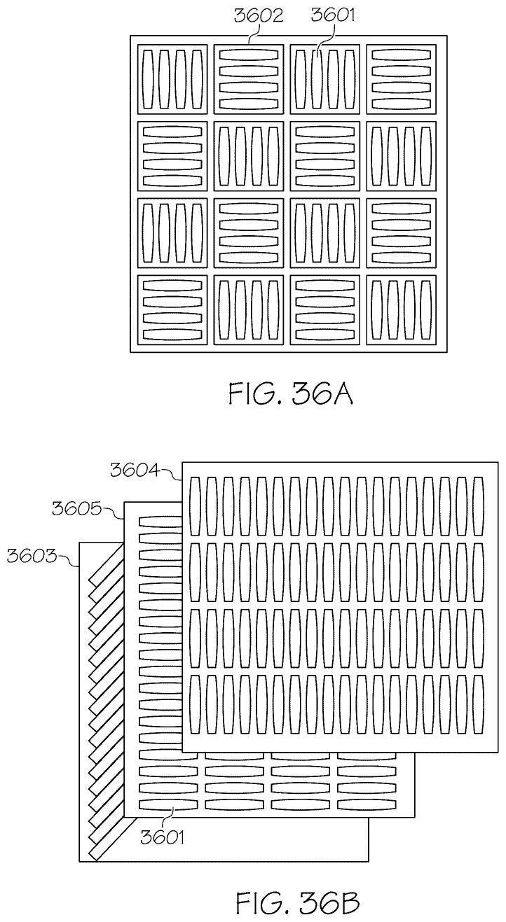

Referring now to FIG. 36A, FIG. 36A illustrates individual coil elements 3601 being grouped together and having those groups being arranged orthogonal to each other in accordance with an embodiment of the present disclosure.

FIG. 36A illustrates multiple versions of coil arrays 3602 of coil elements 3601. In one embodiment, one or more individual coil elements 3601 are closed polygons with sharp or rounded corners.

In one embodiment, two or more individual coil elements 3601 are grouped together in the same orientation and placed orthogonal to groups around it. This helps in generating the desired magnetic field pattern to actuate mover 201 in a desired fashion.

Referring now to FIG. 36B, FIG. 36B illustrates individual coil elements 3601 in different orientations stacked in different planes in accordance with an embodiment of the present disclosure.

In one embodiment, individual coil elements 3601 are grouped in the same orientation in one layer (e.g., layer #3 3603) and two or more layers (e.g., layer #1 3604 and layer #2 3605) with individual coil elements 3601 at different orientations are stacked together. As the layer keeps getting away from the magnet array surface, the thickness of the copper trace (e.g., copper trace 3402 of FIG. 34D) of the individual coil element 3601 keeps getting larger because the coils would need to carry more current to create an actuation force.

A discussion regarding the control architecture in the design of the planar motor based positioning stage is provided below.

The control architecture of the planar motor describes the manner in which current flowing through each coil (e.g., coil 3301, 3401, 3501, 3601) in the coil array (e.g., coil array 3300) is controlled. This depends on the magnet size, magnet pitch, coil array layout, precision requirements, and commutation algorithm.

In one embodiment, each coil (e.g., coil 3301, 3401, 3501, 3601) is modelled independently and the current flowing through each coil (e.g., coil 3301, 3401, 3501, 3601) is calculated separately, i.e., each coil has its own phase. This provides flexibility of actuation of the mover (e.g., mover 201) in in-plane and out-of-plane axes.

In one embodiment, two or more coils (e.g., coil 3301, 3401, 3501, 3601) are grouped together in terms of current control, i.e., multiple coils are in the same phase. This provides an advantage of a significantly lesser number of controllers/drivers for the overall control of the stage. It also reduces computation and controller workload.

A discussion regarding magnet array fabrication in the design of the planar motor based positioning stage is provided below.

In one embodiment, magnets (e.g., magnets 2801) are large enough to manually assemble them in the desired orientation.

In one embodiment, specialized jigs are prepared to load magnets (e.g., magnets 2801) in a predetermined orientation and are brought together on a substrate to achieve the desired magnet orientation, especially for Halbach arrays.

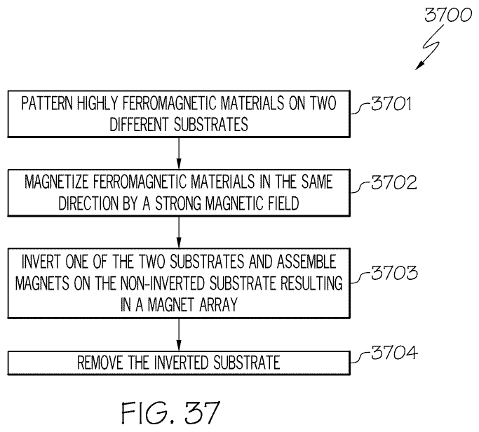

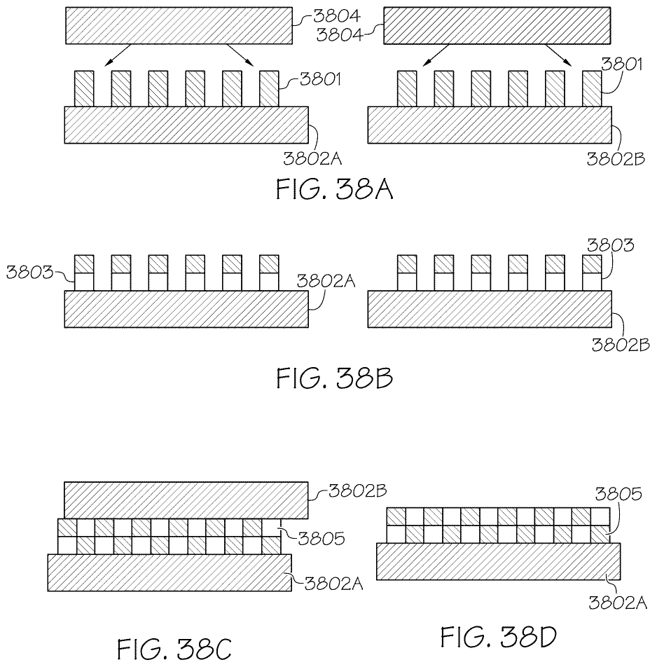

FIG. 37 is a flowchart of a method 3700 for fabricating an array of magnets (e.g., magnets 2801) in accordance with an embodiment of the present disclosure. FIGS. 38A-38D depict the cross-sectional views for fabricating an array of magnets (e.g., magnets 2801) using the steps described in FIG. 37 in accordance with an embodiment of the present disclosure.

Referring to FIG. 37, in conjunction with FIGS. 38A-38D, in step 3701, highly ferromagnetic materials 3801 (e.g., cobalt, nickel, iron, gadolinium, neodymium, steel, magnetite, etc.) are patterned on two different substrates 3802A, 3802B as shown in FIG. 38A.

In one embodiment, magnets are significantly small and cannot be assembled directly. Hence, a highly ferromagnetic material 3801 is patterned on two substrates, such as substrates 3802A, 3802B, as shown in FIG. 38A. The patterns on both substrates 3802A, 3802B are complementary so that they form a single array when assembled together.

In step 3702, ferromagnetic materials 3801 are magnetized (magnets 3803) in the same direction by a strong magnetic field 3804 as shown in FIGS. 38A-38B. That is, the patterns on both substrates 3802A, 3802B are exposed to highly strong magnetic fields 3804 for magnetization of the pillars.

In step 3703, one of the two substrates, such as substrate 3802B is inverted and magnets 3803 are assembled on the non-inverted substrate, such as substrate 3802A, resulting in a magnet array 3805 with an alternate polarity as shown in FIG. 38C. Such a magnet array 3805 is formed due to the combination of the complementary patterns on substrates 3802A, 3802B, resulting in magnet array 3805 with alternate polarity. In one embodiment, substrate 3802B is inverted and the magnetized pillars are bonded to substrate 3802A using adhesive.

In step 3704, the inverted substrate, such as substrate 3802B, is removed as shown in FIG. 38D.

The following discusses non-commutative planar-motor (electromagnetic) based actuation.

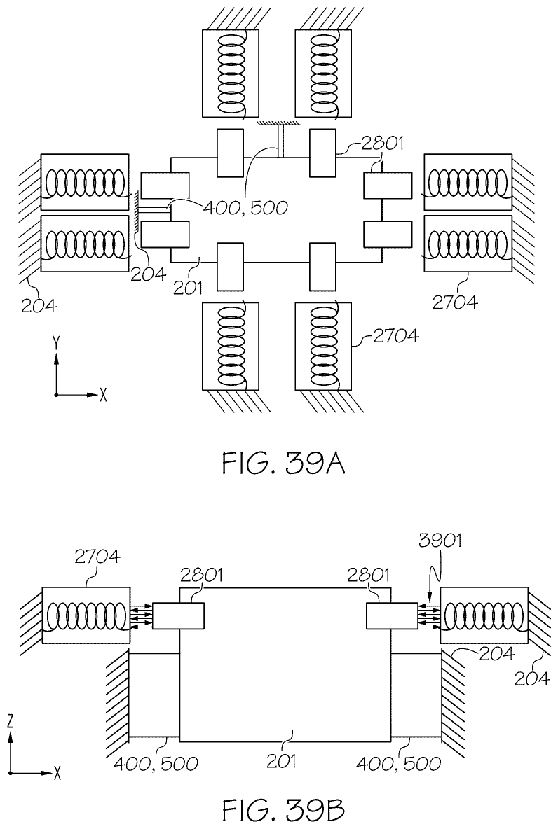

Referring now to FIGS. 39A-39B, FIG. 39A illustrates atop view of non-commutative planar-motor (electromagnetic) based actuation in accordance with an embodiment of the present disclosure. FIG. 39B illustrates a front view of non-commutative planar-motor (electromagnetic) based actuation in accordance with an embodiment of the present disclosure.

As shown in FIGS. 39A-39B, inductive elements 2704, including coils (e.g., coils 3301, 3401, 3501, 3601), and magnets 2801 interact with each other to produce actuation force. Since magnets 2801 do not interact with multiple coils, a commutation algorithm is not required.

FIGS. 39A-39B show the schematic of planar-motor (electromagnetic) based actuation of central stage/mover 201 with no commutation required. In one embodiment, one or more in-plane flexure mechanisms (e.g., in-plane flexure mechanisms 400, 500) are any of the in-plane flexure mechanisms discussed herein.

In one embodiment, there are one or more permanent magnets 2801 attached to mover 201.

In one embodiment, one or more inductive elements 2704 are placed aligning with the permanent magnets 2801. Current is passed through these inductive elements 2704 and the resulting magnetic field 3901 interacts with the permanent magnet 2801, creating a moving force which acts on mover 201, and as a result, mover actuation is obtained.

In one embodiment, one or more inductive elements 2704 are coils (e.g., coils 3301, 3401, 3501, 3601) as discussed above. Such current carrying coils can generate a magnetic field which interacts with the permanent magnets 2801 to give the desired actuation force. In one embodiment, the axis of the coil (e.g., coil 3301, 3401, 3501, 3601) is coincident to a corresponding magnet pole axis.

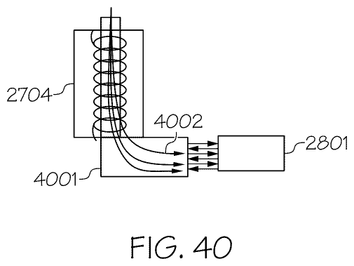

FIG. 40 illustrates an exemplary coil (e.g., coils 3301, 3401, 3501, 3601) and magnet (e.g., 2801) arrangement in accordance with an embodiment of the present disclosure.

In one embodiment, the coil (e.g., coils 3301, 3401, 3501, 3601) of inductive element 2704 is arranged in the orthogonal direction as compared to the one in FIGS. 39A-39B.

In one embodiment, a conductor 4001 is attached to inductive element 2704 as shown in FIG. 40, which interacts with the magnetic field of the coil and bends and extends it (see 4002) so that the resultant magnetic field can interact with the permanent magnets 2801 to get the desired actuation. This orientation improves the packing efficiency of the coils.

In one embodiment, conductor 4001 interacts with the magnetic field generated by the coil (e.g., coil 3301, 3401, 3501, 3601) of inductive element 2704, resulting in the bending and extension of the magnetic field in such a way that it can interact with permanent magnet 2801 in the orthogonal direction to produce the actuation force. In one embodiment, the axis of the coil (e.g., coil 3301, 3401, 3501, 3601) is not coincident to a corresponding magnet pole axis. The following discusses coil fabrication for non-commutative planar-motor actuation mechanisms.

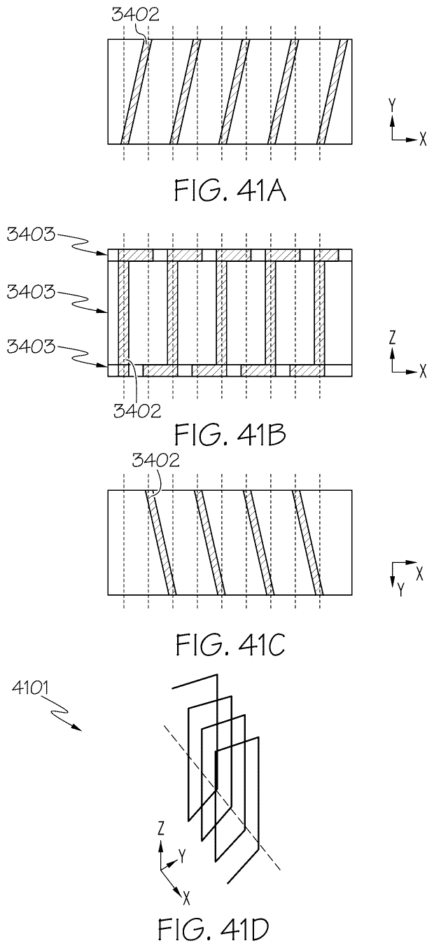

Referring now to FIGS. 41A-41D, FIG. 41A illustrates a top view of copper traces 3402 forming a square helical coil structure 4101 in accordance with an embodiment of the present disclosure. FIG. 41B illustrates a front view of copper traces 3402 forming a square helical coil structure 4101 in accordance with an embodiment of the present disclosure. FIG. 41C illustrates a bottom view of copper traces 3402 forming a square helical coil structure 4101 in accordance with an embodiment of the present disclosure. FIG. 41D illustrates the resultant square helical coil structure 4101 in accordance with an embodiment of the present disclosure.

FIGS. 41A-41D show the schematic for an exemplary coil structure and fabrication technique. In one embodiment, one or both of the top and bottom layers of the coil have copper traces 3402 that change plane to get multiple turns, resulting in a coil, such as a square helical coil structure 4101. Current flowing through the resultant coil structure 4101 would induce a magnetic field which can interact with the permanent magnets (e.g., permanent magnets 2801) and produce actuation force as desired.

In one embodiment, square helical coil structure 4101 is fabricated using the MEMS (micro-electro-mechanical systems) fabrication technique.

The following discusses metrology methods to obtain position feedback for a precise closed loop control architecture.

In one embodiment, one or more sensors or sensing systems are involved in sensing position of the stage in the X, Y, and θ_{Z} directions.

In one embodiment, one or more sensors are capacitive sensors. In one embodiment, one or more capacitive sensors have capacitive probes attached to the mover (e.g., mover 201). In one embodiment, one or more capacitive sensors have capacitive probes attached to the stator (e.g., stator 2601).

In one embodiment, one or more sensors are laser sensors. In one embodiment, the light sensor has a light emitting probe which emits light of a certain wavelength along a certain direction. In one embodiment, there is a read-head which collects light reflected from a surface to which the light emitting probe threw the light beam. The time lag of the reflected light gives the distance of the surface onto which the light was incident from the laser sensor. In one embodiment, the laser sensor is on the mover (e.g., mover 201) and throws light beam on the surface of the stator (e.g., stator 2601). In one embodiment, the laser sensor is on the stator (e.g., stator 2601) and throws light on the surface of the mover (e.g., mover 201).

In one embodiment, one or more sensing systems are interferometry based systems. In one embodiment, there are one or more microscopes emitting light on the substrate the stage is carrying and receives images. In one embodiment, the substrate and the template have alignment marks, which overlay and form fringe patterns, which can be observed from the microscope images. These fringe pattern indicate the relative alignment error between the substrate and the template, which serves as a feedback for the short-stroke stage, and the stage is actuated to eliminate the alignment error in closed loop fashion.

In one embodiment, actuation in one or more of the X, Y, and θ_{Z} directions is obtained using piezoelectric actuators. In-plane flexure mechanisms (e.g., in-plane flexure mechanisms 400, 500) are used to enable motion in one or more of the X, Y, and θ_{Z} directions and to passively support one or more of Z, θ_{X}, and θ_{Y}. Out-of-plane flexures (e.g., flexures 203) are used to transfer the actuator motion to the mover (e.g., mover 201).

In one embodiment, actuation in one or more of the X, Y, and θ_{Z} directions is obtained using piezoelectric actuators, with out-of-plane flexure mechanisms (e.g., out-of-plane flexure mechanisms 1100, 1200) to transmit the motion of the actuators (e.g., actuators 901) to the mover (e.g., mover 201), and in-plane flexure mechanism (e.g., in-plane flexure mechanism 400, 500) to enable motion in one or more of the X, Y, and θ_{Z} directions. The support for one or more of the Z, θ_{X}, and θ_{Y} directions is obtained using in-plane flexures (e.g., flexures 203) and liquid film (e.g., liquid film 2705).

In one embodiment, actuation in one or more of the X, Y, and θ_{Z} directions is obtained using non-commutative planar motor based actuation. In-plane flexure mechanism (e.g., in-plane flexure mechanism 400, 500) and liquid film (e.g., liquid film 2705) are used to provide passive support along one or more of the Z, θ_{X}, and θ_{Y} directions.

In one embodiment, actuation in one or more of the X, Y, and θ_{Z} directions is obtained using commutative planar motor based actuation, and passive support in one or more of the Z, θ_{X}, and θ_{Y} directions is given by in-plane flexure mechanisms (e.g., in-plane flexure mechanisms 400, 500) and/or liquid film (e.g., liquid film 2705).

In one embodiment, actuation in one or more of the X, Y, and θ_{Z} directions is obtained using commutative planar motor based actuation, and passive support in one or more of the Z, θ_{X}, and θ_{Y} directions is given by the compliance control enabled commutative algorithm for mover levitation along the Z direction.

As a result of the foregoing, the principles of the present disclosure provide a means for designing nano-precise short stroke stages for actuation in X, Y and/or θ_{Z}, with sub-50 nm precision and active or passive control in θ_{X}, θ_{Y} and Z.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A system for aligning and bonding four or more dies with respect to a substrate, comprising:
four or more stage modules utilized to enable said aligning of said four or more dies with respect to said substrate, wherein said aligning is performed with sub-50 nm alignment precision, wherein said four or more stage modules are actuated along one or more of X, Y, and θ_{Z} directions.

2. The system as recited in claim 1, wherein said actuation is enabled by piezoelectric and/or electromagnetic methods.

3. The system as recited in claim 1, wherein motion along one or more of Z, θ_{X}, and θ_{Y} directions is supported passively.

4. The system as recited in claim 1 further comprising:
an in-plane flexure mechanism, wherein said actuation along one or more of said X, Y, and θ_{Z} directions is enabled by said in-plane flexure mechanism that comprises one or more cross-flexure elements.

5. The system as recited in claim 1, wherein motion for said actuation along one or more of said X, Y, and θ_{Z} directions is transferred from actuators through one or more double slider out-of-plane mechanisms.

6. The system as recited in claim 1, wherein motion for said actuation along one or more of said X, Y, and θ_{Z} directions is transferred from actuators through one or more lever type out-of-plane mechanisms.

7. The system as recited in claim 3 further comprising:
a mechanism for said passive support along one or more of said Z, θ_{X}, and θ_{Y} directions consists of a two degrees of freedom flexural hinge, serially connected with blade flexures.

8. The system as recited in claim 1 further comprising:
one or more thermal actuators, wherein said actuation along one or more of said X, Y, and θ_{Z} directions is enabled by said one or more thermal actuators.

9. The system as recited in claim 1 further comprising:
actuators through which said actuation along one or more of said X, Y, and θ_{Z} directions are packed along an X axis and/or a Y axis.

10. The system as recited in claim 1 further comprising;
actuators through which said actuation along one or more of said X, Y, and θ_{Z} directions are packed along a Z-axis.

11. The system as recited in claim 1 further comprising:
one or more actuator-stage interfaces through which motion in one or more of said X, Y, and θ_{Z} directions are protected by a mechanism for actuator stability.

12. The system as recited in claim 3, wherein said passive support is enabled by liquid film, wherein said liquid film is between a stator surface and a mover surface.

13. The system as recited in claim 3, wherein said passive support is enabled by liquid film, wherein said liquid film is between a stator die and said substrate.

14. The system as recited in claim 1, wherein said actuation along one or more of said X, Y, and θ_{Z} directions is enabled by commutative planar motor based actuation that has helical coils which are fabricated in a layer-by-layer fashion.

15. The system as recited in claim 1, wherein said actuation along one or more of said X, Y, and θ_{Z} directions is enabled by non-commutative planar motor based actuation.

16. The system as recited in claim 1, wherein said actuation along one or more of said X, Y, and θ_{Z} directions is enabled by non-commutative planar motor based actuation using a coil, wherein an axis of said coil is coincident to a corresponding magnet pole axis.

17. The system as recited in claim 1, wherein said actuation along one or more of said X, Y, and θ_{Z} directions is enabled by non-commutative planar motor based actuation using a coil, wherein an axis of said coil is not coincident to a corresponding magnet pole axis, wherein a conductor is used to bend a magnetic field to interact with a permanent magnet's magnetic field.

18. The system as recited in claim 1, wherein said actuation along one or more of said X, Y, and θ_{Z} directions is enabled by non-commutative planar motor based actuation using a coil, wherein said coil is a square helix fabricated in a layer-by-layer fashion.

19. The system as recited in claim 3, wherein said passive support is enabled by liquid film, wherein said liquid film is water.

20. The system as recited in claim 1 further comprising:
support flexures extending from a stator, wherein said support flexures are attached to an output block of out-of-plane flexure mechanisms for enabling said actuation in said X, Y, and θ_{Z} directions.
